(19) United States
(12) Patent Application Publication
(10) Pub. No.: US 2012/0193600 A1
(43) Pub. Date: Aug. 2, 2012

(54) VARIABLE RESISTANCE NONVOLATILE MEMORY ELEMENT, METHOD OF MANUFACTURING THE SAME, AND VARIABLE RESISTANCE NONVOLATILE MEMORY DEVICE

(76) Inventors: Atsushi Himeno, Osaka (JP); Kiyotaka Tsuji, Osaka (JP)

(21) Appl. No.: 13/499,961

(22) PCT Filed: Jul. 1, 2011
(86) PCT No.: PCT/JP2011/003785

§ 371 Date: Apr. 3, 2012

(30) Foreign Application Priority Data
Jul. 2, 2010 (JP) 2010-152526

(51) Int. Cl. H01L 47/00; H01L 21/02

(52) U.S. Cl. 257/4; 257/2; 438/382; 257/E47.001; 257/E21.004

(57) ABSTRACT

A variable resistance nonvolatile memory element (10) is formed from a first electrode (101) comprising a material including a metal as a main component, a variable resistance layer (102) having a reversibly changing resistance value in response to applied predetermined electric pulses having different polarities, a semiconductor layer (103) comprising a material including a nitrogen-deficient silicon nitride as a main component, and a second electrode (104). The variable resistance layer (102) includes a first variable resistance layer (102a) adjacent to the first electrode (101) and a second variable resistance layer (102b), both comprising a material including an oxygen-deficient transition metal oxide as a main component. The first variable resistance layer (102a) has a higher oxygen content atomic percentage than the second variable resistance layer (102b). A stacked structure of the variable resistance layer (102), the semiconductor layer (103), and the second electrode (104) functions as a bidirectional diode element (106).

### TECHNICAL FIELD

The present invention relates to a variable resistance nonvolatile memory element having a variable resistance element whose resistance value changes in response to electric pulses applied.

### BACKGROUND ART

With recent advances in digital technology, electronic devices such as portable information devices and home information appliances have been developed to provide higher functionality. As the electronic devices have been developed to provide higher functionality, development of further miniaturized and higher-speed semiconductor elements is progressing at a high pace. Among them; the use of large-capacity nonvolatile memories which are typified by a flash memory has been expanding at a rapid pace. Furthermore, as next-generation new nonvolatile memories which have a potential to replace flash memory, a variable resistance nonvolatile memory device using a variable resistance element has been researched and developed. As defined herein, the variable resistance element refers to an element which has a characteristic in which a resistance value changes reversibly in response to electric signals and is further able to store information corresponding to the resistance value in a nonvolatile manner.

As an example of a large-capacity nonvolatile memory device incorporating the variable resistance elements, a crosspoint nonvolatile memory device has been proposed. In a crosspoint nonvolatile memory device, as a single memory unit, a memory cell having a 1D1R (one diode one resistor) structure made up from a variable resistance element and a diode element as a switching element electrically connected in series is preferably used.

As a first example, FIG. 13A is a cross-sectional view taken along the direction of a bit line 210 of a nonvolatile semiconductor memory device 60 containing a conventional variable resistance element memory cell including a memory cell 280, the bit line 210, and a word line 220 of (see PTL 1). A variable resistance element 260 includes a variable resistance layer 230 for storing information according to a change in an electric resistance because of electric stress applied thereto, and an upper electrode 240 and a lower electrode 250 placed on either side of the variable resistance layer 230.

Formed on the variable resistance element 260 is a two-terminal nonlinear element 270 having a nonlinear current-voltage characteristic for flowing a current bidirectionally. The memory cell 280 is formed of a series circuit including the variable resistance element 260 and the nonlinear element 270. The nonlinear element 270 is a two-terminal element having a nonlinear current-voltage characteristic similar to that of a diode in which a current changes inconstantly with respect to a voltage change. Moreover, the bit line 210 serving as an upper line is connected electrically to the nonlinear element 270, and the word line 220 serving as a lower line is electrically connected to the lower electrode 250 of the variable resistance element 260.

Because current flows bidirectionally when rewriting the memory cell 280, a varistor (ZnO or SrTiO₃) having a current-voltage characteristic which is bidirectionally symmetric and nonlinear is used as the nonlinear element 270. With the above configuration, it is possible to flow a current with a current density of 30 kA/cm² or higher which is required for rewriting for the variable resistance element 260 and achieve a larger capacity.

Moreover, as a second example, FIG. 13B is a perspective view of a resistive memory element (see PTL 2). The resistive memory element 70 includes a first electrode E1, a second electrode E2 separated from the first electrode E1, a variable resistance layer R1 comprising a material having a variable resistance characteristic Interposed between the first electrode E1 and the second electrode E2, an intermediate electrode M1, and a first structure S1 made up of a switching element D1 electrically connected to the variable resistance layer R1 by the intermediate electrode M1. Furthermore, a second structure S2 having the same configuration as the first structure S1 is disposed on the second electrode E2.

By forming at least either the first electrode E1 or the second electrode E2 as an alloy layer comprising a noble metal such as platinum or iridium, variable resistance characteristics and adhesiveness to other layers can both be achieved and manufacturing costs can be decreased. Moreover, it is preferable that the switching element be a p-n diode having a stacked structure of a p-type oxide layer and an n-type oxide layer, or having a stacked structure of p-type silicon and n-type silicon.

### [Citation List]

### [Patent Literature]

### [PTL 1] Japanese Unexamined Patent Application Publication No. 2006-203098.

### [PTL 2] Japanese Unexamined Patent Application Publication No. 2008-300841.

### SUMMARY OF INVENTION

### [Technical Problem]

However, in the conventional structure described in the first example, a stacked structure of six layers including the bit line and the word line makes up the variable resistance element and the diode element. The upper electrode 240, variable resistance layer 230, lower electrode 250, and nonlinear element 270 are patterned at the same time in the direction of the bit line 210 when the bit line 210 is processed, and in the direction of the word line 220 when the word line is processed. In other words, the memory cell 280 is formed only at the crosspoint of the word line 220 and the bit line 210 by what is called double patterning.

With this method of manufacturing, because the layers to be patterned become thicker and because a plurality of layers comprising different materials are processed at the same time, patterning by etching is difficult, making this structure unsuitable for miniaturization.

Moreover, a problem also arises with respect to the second example in which the manufacturing method becomes complicated due to the resistive memory element requiring a stacked structure of six layers including the upper and lower electrodes. Moreover, because the switching element is a p-n diode, it is suitable for a unipolar variable resistance element, that is, a variable resistance element in which a write voltage increasing the resistance and a write voltage decreasing the resistance have the same polarity. However, when a p-n diode is paired with a bipolar variable resistance element, that is, a variable resistance element in which the polarity of a write voltage increasing the resistance has the reverse polarity of a write voltage decreasing the resistance, a problem arises in which a sufficient amount of write voltage cannot be applied to the variable resistance element when the diode is in reverse bias.

Accordingly, the object of the present invention is to solve the problems associated with the conventional configuration described above by providing a nonvolatile memory device suitable for high integration and large-capacity storage. The nonvolatile memory device can easily be manufactured with reduced costs and a reduced number of processes by implementing a variable resistance nonvolatile memory element as a simple configuration of a variable resistance element and a bidirectional diode, and applying the simply configured variable resistance nonvolatile memory element to memory cells that are capable of being miniaturized.

### [Solution to Problem]

In order to accomplish the objects described above, an embodiment of the variable resistance nonvolatile memory element according to the present invention includes a first electrode comprising a material including a metal as a main component, a variable resistance layer disposed adjacent to the first electrode in the thickness direction and having a resistance value that changes reversibly in response to predetermined electric pulses having different polarities being applied, a semiconductor layer disposed adjacent to the variable resistance layer in the thickness direction and comprising a material including a nitrogen-deficient silicon nitride as a main component, and a second electrode disposed adjacent to the semiconductor layer in the thickness direction, wherein the variable resistance layer has a stacked structure including a first variable resistance layer and a second variable resistance layer each comprising a material including an oxygen-deficient transition metal oxide as a main component, the first variable resistance layer being adjacent to the first electrode and having an oxygen content atomic percentage that is higher than an oxygen content atomic percentage of the second variable resistance layer, and a stacked structure including the variable resistance layer, the semiconductor layer, and the second electrode functions as a bidirectional diode.

The variable resistance layer may further include a third variable resistance layer interposed between the first variable resistance layer and the second variable resistance layer, and an oxygen-deficient transition metal oxide included in the third variable resistance layer has an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer.

By adopting such a configuration, the resistance changing operation can be performed in the vicinity of the interface between the first electrode and the variable resistance layer stably. This is because, in a mechanism of the resistance changing operation, oxidation and reduction of oxygen in the vicinity of an electrode are dominant, and the resistance changing operation occurs preferentially at the interface where oxygen which contributes to oxidation and reduction is more in amount. Therefore, it is possible to implement a variable resistance nonvolatile memory element with a stable variable resistance characteristic.

It is preferable that the first electrode comprise one of metals including platinum, iridium, palladium, copper, and tungsten, a composite of the metals, or an alloy of the metals, and said second electrode comprises one of metals including tantalum nitride, titanium nitride, and tungsten, or a composite of the metals.

Moreover, it is preferable that an oxygen-deficient transition metal oxide be used in the variable resistance layer.

Moreover, it is preferable that an oxygen-deficient tantalum oxide be used in the variable resistance layer.

It is preferable that the oxygen-deficient tantalum oxide included in the second variable resistance layer have a composition represented by TaO_{y} where 0<y≦1.29. it is further preferable that the oxygen-deficient tantalum oxide included in the second variable resistance layer have a composition represented by TaO_{y} where 0.8≦y≦1.29.

Moreover, it is preferable that nitrogen-deficient silicon nitride be used in the semiconductor layer.

By adopting such a configuration, materials are used in the first electrode and the variable resistance layer which, based on their combination, can perform a resistance changing operation. As a result, a resistance changing operation can be performed in the vicinity of the interface between the first electrode and the variable resistance layer.

Moreover, by using for the variable resistance layer a material having a work function that is higher than the work function of the semiconductor layer, a Schottky barrier is formed at the interface between the variable resistance layer and the semiconductor layer.

It is preferable that the variable resistance layer have a stacked structure including a first variable resistance layer and a second variable resistance layer each comprising the same metal oxide, the first variable resistance layer being adjacent to the first electrode. It is preferable that when the first variable resistance layer has an oxygen content atomic percentage that is higher than an oxygen content atomic percentage of the second variable resistance layer, the second variable resistance layer use a material having a work function that is higher than a work function of the semiconductor layer. A Schottky barrier is formed at the interface between the second variable resistance layer and the semiconductor layer here as well.

Furthermore, by using for the second electrode a material having a work function that is higher than the work function of the semiconductor layer as well, a Schottky barrier is formed at the interface between the semiconductor layer and the second electrode. Accordingly, a variable resistance nonvolatile memory element which has a 1D1R structure made up from a variable resistance element and a bidirectional diode in a stacked structure of four layers including the upper and lower electrodes can be implemented.

In this description, a bidirectional diode is defined as a two-terminal element exhibiting a nonlinear electrical resistance characteristic and having a current-voltage characteristic which is substantially symmetrical with respect to the polarity of an applied voltage. That is, a change in current with respect to an applied voltage that is positive and a change in current with respect to an applied voltage that is negative are substantially symmetrical with respect to an origin 0. Moreover, the two-terminal element has a nonlinear electrical resistance characteristic in which electrical resistance is extremely high when an applied voltage is a critical voltage or lower, and electrical resistance sharply decreases and large current flows when the critical voltage is exceeded.

A Metal-Semiconductor-Metal diode (MSM), a Metal-Insulator-Metal diode (MIM), and a varistor are examples of known two-terminal elements which have this type of characteristic.

By using this type of bidirectional diode element in a variable resistance nonvolatile memory device having a 1D1R structure, write disturbance can be completely avoided in adjacent memory cells in a bipolar variable resistance element that performs a resistance changing operation according the application of electric pulses having different polarities.

Next, an embodiment of the variable resistance nonvolatile memory device according to the present invention includes a plurality of first lines extending in a first direction, a plurality of second lines extending in a second direction which intersects the first direction, and a plurality of memory cells each positioned at a corresponding one of crosspoints of the first lines and the second lines, wherein each of the memory cells includes the variable resistance nonvolatile memory element, the first lines include the first electrodes of the variable resistance nonvolatile memory elements that are connected to each other, and the second lines include the second electrodes of the variable resistance nonvolatile memory elements that are connected to each other.

By adopting such a configuration, a variable resistance nonvolatile memory device capable of large-capacity storage and high integration can be implemented without disposing a switching element such as a transistor.

Moreover, a memory cell can include a variable resistance layer comprising tantalum oxide. Tantalum and tantalum oxide are compatible with a silicon semiconductor process, so, for example, the variable resistance layer comprising tantalum oxide can be filled and formed in the memory cell and processed by chemical mechanical polishing (CMP). Moreover, when forming a memory cell by etching, the memory cell can be miniaturized and the manufacturing process can be simplified because the variable resistance layer of the memory cell comprises tantalum oxide and because noble metals and copper and such which are difficult to dry etch are not included in the memory cell.

Furthermore, because the diode element which includes the semiconductor layer can be formed into a line shape identical to the second electrode, the semiconductor layer can be shaped simultaneously with the second electrode, reducing the number of manufacturing processes. Moreover, because the contact area of the second electrode and the semiconductor layer becomes larger than the contact area of the variable resistance layer and the semiconductor layer, the electric line of force spreads to the vicinity of the second electrode, and the current capacity of the diode element can be increased.

Therefore, it is possible to implement a variable resistance nonvolatile memory element which can easily be manufactured with reduced costs and a reduced number of processes.

Moreover, in addition to a variable resistance nonvolatile memory element and a variable resistance nonvolatile memory device, the present invention can be implemented as a method of manufacturing the variable resistance nonvolatile memory element as well.

### [Advantageous Effects of Invention]

The variable resistance nonvolatile memory element according to the present invention is configured of the stacked structure of four layers including the first electrode, the variable resistance layer which is connected to the first electrode, the semiconductor layer which is connected to the variable resistance layer, and the second electrode which is connected to the semiconductor layer. Here, the variable resistance element is made up from the first electrode and the variable resistance layer, and the diode element is made up from the variable resistance layer, the semiconductor layer, and the second electrode.

The variable resistance nonvolatile memory element has a characteristic in which the variable resistance layer functions as an electrode of the diode element and a Schottky barrier is formed at the interface between the variable resistance layer and the semiconductor layer due to a material being used in the variable resistance layer which has a work function that is higher than the work function of the semiconductor layer. Furthermore, because a Schottky barrier is formed at the interface between the semiconductor layer and the second electrode due to a material being used in the second electrode which has a work function that is higher than the work function of the semiconductor layer as well, a bidirectional MSM diode can be implemented. Accordingly, a 1D1R structure in which the variable resistance element is combined with the diode element can be implemented as a stacked structure of four layers.

Moreover, because a mechanism of the resistance changing operation originates in the oxidation and reduction of the variable resistance layer and a metal or alloy is used in the first electrode which has a standard electrode potential that is higher than the metal or alloy used in the variable resistance layer, oxidation-reduction reactions in the variable resistance layer occur in the vicinity of the interface between the variable resistance layer and the first electrode and a resistance changing operation is performed.

Moreover, by forming the variable resistance layer as a stacked structure of two layers including a layer containing a high concentration of oxygen connected to the first electrode and a layer containing a low concentration of oxygen connected to the semiconductor layer, a resistance changing operation can be performed in the vicinity of the interface between the first electrode and the variable resistance layer. Additionally, since the polarity with which the resistance changes is further stable, a characteristic in which memory is stable can be achieved. This is because the resistance changing operation occurs preferentially at the interface where oxygen which contributes to oxidation and reduction is more in amount.

In this configuration, since oxidation and reduction of the variable resistance layer does not occur in the vicinity of the interface between the variable resistance layer including the layer containing a low concentration of oxygen and the semiconductor layer, the concentration of oxygen does not change in the variable resistance layer in the vicinity of its interface with the semiconductor layer. Thus, the Schottky barrier formed at the interface between the variable resistance layer and the semiconductor layer exhibits a characteristic in which the diode is stable regardless of a resistance changing operation.

Furthermore, by applying a structure suitable for miniaturization and large-capacity storage, that is, a structure made up from a bit line, a word line, and memory cells interposed between the bit lines and word lines, in this four-layered variable resistance nonvolatile memory element, the variable resistance nonvolatile memory device which is suitable for large-capacity storage and high integration and which can easily be manufactured with reduced costs and a reduced number of processes can be implemented.

### BRIEF DESCRIPTION OF DRAWINGS

FIG. 1A is a cross-sectional view showing a configuration of the variable resistance nonvolatile memory element according to the first embodiment of the present invention.

FIG. 1B is a cross-sectional view showing a configuration of the variable resistance nonvolatile memory element according to the first embodiment of the present invention.

FIG. 1C is a cross-sectional view showing a configuration of the variable resistance nonvolatile memory element according to the first embodiment of the present invention.

FIG. 1D is a graph showing a relationship between the configuration of the variable resistance layer and the endurance characteristics of the variable resistance nonvolatile memory element according to the first embodiment of the present invention.

FIG. 2A is a graph showing a current-voltage characteristic of a stand alone diode element of the variable resistance nonvolatile memory element according to the first embodiment of the present invention.

FIG. 2B is a graph showing a variable resistance characteristic when electric pulses are applied to the variable resistance nonvolatile memory element according to the first embodiment of the present invention.

FIG. 2C is a graph showing a relationship between the electrode materials and the current quantity flowing to a comparative example diode element and to the diode element used in the variable resistance nonvolatile memory element according to the first embodiment of the present invention.

FIG. 2D is view of an energy band showing a relationship between the electrode materials and the current quantity of the diode element.

FIG. 3A is a cross-sectional view showing a configuration of the variable resistance nonvolatile memory device according to the second embodiment of the present invention.

FIG. 3B is a cross-sectional view showing a configuration of the variable resistance nonvolatile memory device according to the second embodiment of the present invention.

FIG. 3C is a plain view showing a configuration of the variable resistance nonvolatile memory device according to the second embodiment of the present invention.

FIG. 4A is a cross-sectional view showing a method of manufacturing a main component of the variable resistance nonvolatile memory device according to the second embodiment of the present invention using a damascene process.

FIG. 4B is a cross-sectional view showing a method of manufacturing a main component of the variable resistance nonvolatile memory device according to the second embodiment of the present invention using a damascene process.

FIG. 4C is a cross-sectional view showing a method of manufacturing a main component of the variable resistance nonvolatile memory device according to the second embodiment of the present invention using a damascene process.

FIG. 4D is a cross-sectional view showing a method of manufacturing a main component of the variable resistance nonvolatile memory device according to the second embodiment of the present invention using a damascene process.

FIG. 5A is a cross-sectional view showing a method of manufacturing a main component of the variable resistance nonvolatile memory device according to the second embodiment of the present invention using a damascene process.

FIG. 5B is a cross-sectional view showing a method of manufacturing a main component of the variable resistance nonvolatile memory device according to the second embodiment of the present invention using a damascene process.

FIG. 5C is a cross-sectional view showing a method of manufacturing a main component of the variable resistance nonvolatile memory device according to the second embodiment of the present invention using a damascene process.

FIG. 5D is a cross-sectional view showing a method of manufacturing a main component of the variable resistance nonvolatile memory device according to the second embodiment of the present invention using a damascene process.

FIG. 6A is a cross-sectional view showing a method of manufacturing a main component of the variable resistance nonvolatile memory device according to the second embodiment of the present invention using an etching process.

FIG. 6B is a cross-sectional view showing a method of manufacturing a main component of the variable resistance nonvolatile memory device according to the second embodiment of the present invention using an etching process.

FIG. 6C is a cross-sectional view showing a method of manufacturing a main component of the variable resistance nonvolatile memory device according to the second embodiment of the present invention using an etching process.

FIG. 6D is a cross-sectional view showing a method of manufacturing a main component of the variable resistance nonvolatile memory device according to the second embodiment of the present invention using an etching process.

FIG. 6E is a cross-sectional view showing a method of manufacturing a main component of the variable resistance nonvolatile memory device according to the second embodiment of the present invention using an etching process.

FIG. 7A is a cross-sectional view showing a configuration of the variable resistance nonvolatile memory device according to the third embodiment of the present invention.

FIG. 7B is a cross-sectional view showing a configuration of the variable resistance nonvolatile memory device according to the third embodiment of the present invention.

FIG. 8A is a cross-sectional view showing a method of manufacturing a main component of the variable resistance nonvolatile memory device according to the third embodiment of the present invention using a damascene process.

FIG. 8B is a cross-sectional view showing a method of manufacturing a main component of the variable resistance nonvolatile memory device according to the third embodiment of the present invention using a damascene process.

FIG. 8C is a cross-sectional view showing a method of manufacturing a main component of the variable resistance nonvolatile memory device according to the third embodiment of the present invention using a damascene process.

FIG. 8D is a cross-sectional view showing a method of manufacturing a main component of the variable resistance nonvolatile memory device according to the third embodiment of the present invention using a damascene process.

FIG. 8E is a cross-sectional view showing a method of manufacturing a main component of the variable resistance nonvolatile memory device according to the third embodiment of the present invention using an etching process.

FIG. 9A is a cross-sectional view showing a configuration of the variable resistance nonvolatile memory device according to the fourth embodiment of the present invention.

FIG. 9B is a cross-sectional view showing a configuration of the variable resistance nonvolatile memory device according to the fourth embodiment of the present invention.

FIG. 10A is a cross-sectional view showing a method of manufacturing a main component of the variable resistance nonvolatile memory device according to the fourth embodiment of the present invention using a damascene process.

FIG. 10B is a cross-sectional view showing a method of manufacturing a main component of the variable resistance nonvolatile memory device according to the fourth embodiment of the present invention using a damascene process.

FIG. 10C is a cross-sectional view showing a method of manufacturing a main component of the variable resistance nonvolatile memory device according to the fourth embodiment of the present invention using a damascene process.

FIG. 10D is a cross-sectional view showing a method of manufacturing a main component of the variable resistance nonvolatile memory device according to the fourth embodiment of the present invention using a damascene process.

FIG. 11A is a cross-sectional view showing a method of manufacturing a main component of the variable resistance nonvolatile memory device according to the fourth embodiment of the present invention using a damascene process.

FIG. 11B is a cross-sectional view showing a method of manufacturing a main component of the variable resistance nonvolatile memory device according to the fourth embodiment of the present invention using a damascene process.

FIG. 11C is a cross-sectional view showing a method of manufacturing a main component of the variable resistance nonvolatile memory device according to the fourth embodiment of the present invention using a damascene process.

FIG. 12A is a cross-sectional view showing a configuration of the variable resistance nonvolatile memory device according to the fifth embodiment of the present invention.

FIG. 12B is a cross-sectional view showing a configuration of the variable resistance nonvolatile memory device according to the fifth embodiment of the present invention.

FIG. 13A is a cross-sectional view showing a configuration of a general, conventional variable resistance nonvolatile memory device.

FIG. 13B is a cross-sectional view showing a configuration of a general, conventional variable resistance nonvolatile memory device.

### DESCRIPTION OF EMBODIMENTS

Hereinafter, embodiments of the variable resistance nonvolatile memory element (hereinafter also referred to simply as nonvolatile memory element) and a method of manufacturing the same according to the present invention will be described with reference to the drawings. The constituents designated by the same reference numerals throughout the drawings will not be described repetitively in some cases. In addition, in the drawings, the constituents are schematically depicted for easier understanding. Therefore, the shapes and scales of the constituents are not depicted correctly.

### First Embodiment

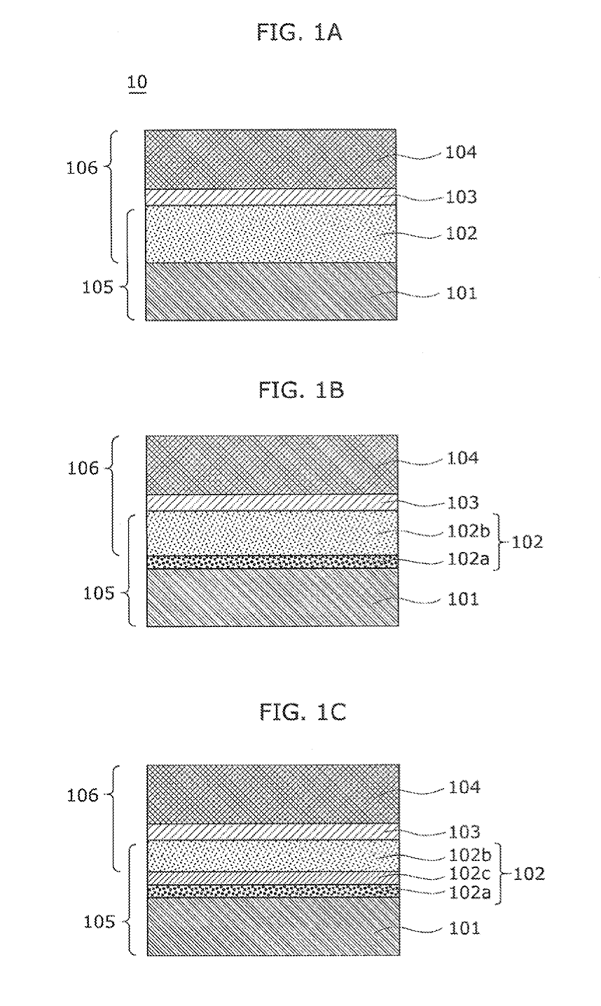

FIG. 1A and FIG. 1B are cross-sectional views showing a configuration of a nonvolatile memory element 10 according to the first embodiment of the present invention.

As shown in FIG. 1A, the nonvolatile memory element 10 according to the first embodiment of the present invention is made up from a first electrode 1.01, a second electrode 104, and a variable resistance layer 102 and a semiconductor layer 103 which are interposed between the two electrodes. A variable resistance element 105 is made up from the first electrode 101 and the variable resistance layer 102, and a diode element 106 is made up from the variable resistance layer 102, the semiconductor layer 103, and the second electrode 104.

Here, the variable resistance layer 102 of the variable resistance element 105 comprises a transition metal oxide comprising oxygen-deficient tantalum oxide. Here, an oxygen-deficient transition metal oxide is an oxide when, for instance if a transition metal oxide having a composition represented by MO_{X} in which M represents a transition metal and O represents oxygen, the composition x of oxygen O is less than when in a stoichiometrically stable state (typically exhibits a characteristic of a semiconductor in this case; typically an insulator when in a stoichiometrically stable state). When the transition metal is tantalum, a tantalum oxide having a composition that satisfies 0<x<2.5 can be said to be an oxygen-deficient tantalum oxide because the stoichiometrically stable state of tantalum oxide is Ta₂O₅. By using a variable resistance layer comprising the preceding oxygen-deficient tantalum oxide, an electric resistance value changes reversibly in response to predetermined electric pulses having different polarities being applied, and a nonvolatile memory element in which a resistance changing phenomenon occurs and a characteristic in which rewriting is stable is gained can be implemented. The details with respect to operational characteristics of and methods of manufacturing a basic configuration of the variable resistance element such as this are disclosed in related patent literature WO 2008/059701 (PTL 3).

It is to be noted that the variable resistance layer is not limited to the use of the above oxygen-deficient tantalum oxide. Other oxygen-deficient transition metal oxides may also be used, such as hafnium oxide or zirconium oxide. When hafnium oxide is used, it is preferable that the hafnium oxide have a composition that approximately satisfies 0.9≦x≦1.6 when expressed as HfOₓ. Moreover, when zirconium oxide is used, it is preferable that the zirconium oxide have a composition that approximately satisfies 0.9≦x≦1.4 when expressed as ZrOₓ. By using a composition in this range, a resistance changing operation which is performed stably can be realized.

Moreover, as shown in FIG. 1B, the variable resistance layer 102 may be formed as a stacked structure including the first variable resistance layer 102a and the second variable resistance layer 102b. When this is the case, the first variable resistance layer 102a is connected to the first electrode 101, and the first variable resistance layer 102a has an oxygen content atomic percentage that is higher than the oxygen content atomic percentage of the second variable resistance layer 102b.

The details with respect to operational characteristics of and methods of manufacturing a basic configuration of the variable resistance element when the variable resistance layer is made up a stacked structure of two layers such as described are depicted in related patent literature WO 2008/149484 (PTL 4).

As is shown in FIG. 1B, when the variable resistance layer is made up of a stacked structure of two layers, the second variable resistance layer 102b included in the variable resistance layer 102 and having a low resistance value functions as one of the electrodes of the diode element 106. Moreover, a change in resistance of the variable resistance element 105 mainly occurs at the first variable resistance layer 102a which has a higher oxygen content atomic percentage within the variable resistance layer 102. Specifically, the first variable resistance layer 102a having a high oxygen content atomic percentage exhibits a change in resistance as a result of an exchange of oxygen with the second variable resistance layer 102b.

Therefore, the nonvolatile memory element having the variable resistance layer 102 made up from two layers can choose the first variable resistance layer 102a for its variable resistance characteristic, while on the other hand the second variable resistance layer 102b can be chosen for its diode characteristic.

Moreover, as shown in FIG. 1C, the variable resistance layer 102 may have a third variable resistance layer 102c which is interposed between the first variable resistance layer 102a and the second variable resistance layer 102b. in this case, the oxygen-deficient transition metal oxide included in the third variable resistance layer 102c has an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer.

FIG. 1D is a graph showing the endurance characteristics of the nonvolatile memory element with the variable resistance layer made up of a two-layered structure in one sample, and with the variable resistance layer made up of a three-layered structure in another sample. The configurations of the variable resistance layers are represented on the horizontal axis of the graph. The sample shown on the left and in the middle of the graph is the two-layered structure which includes the first variable resistance layer 102a which is a high-resistance layer, and the second variable resistance layer 102b which is an oxygen-deficient layer having a high oxygen content atomic percentage in comparison with the high-resistance layer. The sample shown on the right of the graph is the three-layered structure which includes the first variable resistance layer 102a which is a high-resistance layer, the second variable resistance layer 102b which is an oxygen-deficient layer, and the third variable resistance layer 102c. The vertical axis on the left represents the rate of failure to reach a high resistance state, or HR failure, or failure to reach a low resistance state, or LR failure (shown in an arbitrary unit). The vertical axis on the right represents a pass rate of an endurance characteristic after pulse application was repeated 100,000 times on the nonvolatile memory elements, which include the variable resistance layer, of the memory cell array.

In FIG. 1D, the LR failure rate (the bar positioned on the right of the pairs) and the HR failure rate (the bar positioned on the left of the pairs) are shown in pairs as data corresponding with the samples shown on the left, middle, and right of the graph and to the vertical axis on the left. Moreover, three black points are plotted on the graph as data corresponding to the vertical axis on the right.

In the nonvolatile memory element with the variable resistance layer 102 having a two-layered structure, as the resistivity of the oxygen-deficient layer (the first variable resistance layer 102a) is decreased, the number of times HR failure occurs increases. Conversely, as the resistivity of the oxygen-deficient layer is increased, the number of times LR failure occurs increases. The bars on the graph corresponding with the samples shown in the middle and on the left of FIG. 1D show this trade-off relationship. In contrast, the bars on the graph and the plot of black points corresponding with the sample shown on the right of FIG. 1D show that, by forming the oxygen-deficient layer as a two-layered structure, that is, by forming the variable resistance layer 102 as a three-layered structure, the occurrence of both HR and LR failure changes for the better, and the pass rate of the endurance characteristic changes for the better. That is, by forming the variable resistance layer 102 as a three-layered structure, a nonvolatile memory element having a better endurance characteristic can be gained.

When the variable resistance layer 102 is formed as a stacked structure of three layers, the composition and thickness of each of the variable resistance layers is determined as described below. The first variable resistance layer 102a, with respect to its composition and thickness, is made so as to be close to its stoichiometric composition in order to selectively facilitate oxidation-reduction reactions and eliminate the need for a forming operation (an operation electrically forming the first variable resistance layer 102a which is the high-resistance layer). The composition and thickness of the first variable resistance layer 102a determines the readout current when in a high resistance state. The third variable resistance layer 102c, with respect to its composition and thickness, is made so as to be the layer supplying and receiving oxygen to the first variable resistance layer 102a as the parent body variable resistance layer and to cause a change in resistance stably, as well as to alleviate sharp changes in its oxygen concentration profile with the first variable resistance layer 102a. The second variable resistance layer 102b, with respect to its composition and thickness, is made so as to increase the readout current when in a low resistance state and widen the readout window, as well as to be suitable as an electrode of a diode.

In a stacked structure such as this, when using tantalum oxide for the first variable resistance layer and the second variable resistance layer, it is preferable the first variable resistance layer 102a (a first tantalum oxide layer) have an oxygen content atomic percentage of 67.7 atm % or higher (when expressed as TaO_{y}, where 2.1≦y), and the second variable resistance layer 102a (a second tantalum oxide layer) have an oxygen content atomic percentage no less than 44.4 atm % and no more than 65.5 atm % (when expressed as TaOₓ, where 0.8≦x≦1.9). Moreover, when the variable resistance layer 102 is formed as a three-layered structured, the third variable resistance layer 102c (a third tantalum oxide layer) has an oxygen content atomic percentage of a value intermediate between the oxygen content atomic percentage of the first variable resistance layer 102a and the oxygen content atomic percentage of the second variable resistance layer 102b. However, in addition to these value ranges, as will be described later, it is preferable that the oxygen content atomic percentage of the second variable resistance layer 102b (the second tantalum oxide layer) be chosen so a preferable Schottky barrier is formed between the second variable resistance layer 102b and the semiconductor layer 103.

By designing the first variable resistance layer 102a, which is connected to the first electrode 101, to have an oxygen content atomic percentage that is higher than the oxygen content atomic percentage of the second variable resistance layer 102b, a change in resistance in response to oxidation and reduction can occur more easily in the vicinity of the interface between the first variable resistance layer 102a and the first electrode 101. Accordingly, the variable resistance element 105 having a stable variable resistance characteristic in which the variation of an initial resistance is small can be achieved. Additionally, it is preferable that the thickness of the first tantalum oxide layer be no less than 1 nm and no more than 10 nm.

When the stacked structure comprises tantalum oxide, after the first tantalum oxide layer 102a (TaO_{y}) is formed on the first electrode 101 through sputtering in argon gas using a target of Ta₂O₅, an oxygen-deficient the second tantalum oxide layer 102b (TaOₓ) which has a lower oxygen content atomic percentage than the first tantalum oxide layer 102a can be formed on the first tantalum oxide layer 102a through reactive sputtering in argon gas and oxygen gas using a target of Ta. The first tantalum oxide layer 102 (TaO_{y}) may be formed through sputtering in argon gas and oxygen gas. Moreover, the oxygen content atomic percentage of the second tantalum oxide layer 102b (TaOₓ) can be changed by adjusting the flow rate of the oxygen gas accordingly at the time of sputtering. The second tantalum oxide layer 102b (TaOₓ) may also be formed after a layer of a predetermined film thickness is first formed by the same method as the second tantalum oxide layer 102b (TaOₓ) and the layer is changed into the first tantalum oxide layer 102a having a high oxygen content atomic percentage through an oxidation process.

Above, the first variable resistance layer 102 having a high oxygen content atomic percentage was described in the case that it is formed below the second variable resistance layer 102b having a low oxygen content atomic percentage. The reverse formation is simple furthermore, as the surface of the second tantalum oxide layer 102b (TaOₓ) after being formed on the first electrode 101 can be oxidized using an oxidation process such as plasma oxidation.

It is to be noted that, a transition metal oxide layer was made up of a stacked structure comprising tantalum oxide in the described example, however, a stacked structure comprising hafnium oxide or a stacked structure comprising zirconium oxide, for instance, is also acceptable.

When hafnium oxide is used in the stacked structure, it is preferable that a first hafnium oxide have a composition that satisfies 1.8<y when expressed as HfO_{y} and a second hafnium oxide have a composition that approximately satisfies 0.9≦x≦1.6 when expressed as HfOₓ, and it is preferable that a film thickness of the first hafnium oxide be no less than 3 nm and no more than 4 nm.

When zirconium oxide is used in the stacked structure, it is preferable that a first zirconium oxide have a composition that satisfies 1.9<y when expressed as ZrOy and a second zirconium oxide have a composition that approximately satisfies 0.9≦x≦1.4 when expressed as ZrOx, and it is preferable that a film thickness of the first zirconium oxide be no less than 1 nm and no more than 5 nm.

A stacked structure comprising either hafnium oxide or zirconium oxide is formed using the same methods as a stacked structure comprising tantalum oxide. For example, when hafnium oxide is used, firstly a thin film comprising the first hafnium oxide (HfO_{y}) with a range of thickness no less than 3 nm and no more than 4 nm can be formed on the first electrode 101 through sputtering in argon gas using a target of HfO₂. Next, on a first hafnium oxide layer (HfO_{y}), a second hafnium oxide layer (HfOₓ) of a desired thickness is formed to have an oxygen content atomic percentage of approximately 0.9≦x≦1.6. By doing so, a variable resistance layer comprising hafnium oxide and having a stacked structure with different oxygen content atomic percentages can be formed. Moreover, same as in the case when tantalum oxide is used, the oxygen content atomic percentage of the second hafnium oxide layer can easily be adjusted by changing the flow rate of the oxygen gas with respect to the argon gas in the reactive sputtering. It is to be noted that a substrate does not especially need to be heated; room temperature is acceptable.

Moreover, when it is desirable to form the first hafnium oxide layer on the second hafnium oxide layer, the first hafnium oxide layer can be formed by exposing the surface of the second hafnium oxide layer to a plasma of argon and oxygen gas after formation of the second hafnium oxide layer. In this case, the thickness of the first hafnium oxide layer can easily be adjusted by changing the exposure time to the plasma of argon and oxygen gas.

When the composition of the first hafnium oxide layer expressed as HfO_{y} satisfies 1.9<y, and the composition of the second hafnium oxide layer expressed as HfO_{X} satisfies 0.9≦x≦1.6, and the thickness of the first hafnium oxide layer is no less than 3 nm and no more than 4 nm, a stable variable resistance characteristic can be realized.

When zirconium oxide is used, firstly a thin film comprising the second zirconium oxide (ZrO_{y}) with a range of thickness no less than 1 nm and no more than 5 nm can be formed on the first electrode 101 through sputtering in argon gas using a target of ZrO₂. Next, by forming a second zirconium oxide layer of a desired thickness on a first zirconium oxide layer, a variable resistance layer comprising zirconium oxide and having a stacked structure with different oxygen content atomic percentages can be formed

Moreover, same as in the case when tantalum oxide is used, the oxygen content atomic percentage of the second zirconium oxide layer can easily be adjusted by changing the flow rate of the oxygen gas with respect to the argon gas in the reactive sputtering. It is to be noted that a substrate does not especially need to be heated; room temperature is acceptable.

Moreover, when it is desirable to form the first zirconium oxide layer on the second zirconium oxide layer, the first zirconium oxide layer can be formed by exposing the surface of the second zirconium oxide layer to a plasma of argon and oxygen gas after formation of the second zirconium oxide layer. In this case, the thickness of the first zirconium oxide layer can easily be adjusted by changing the exposure time to the plasma of argon and oxygen gas.

When the composition of the first zirconium oxide layer expressed as ZrO_{y} satisfies 1.9<y, and the composition of the second zirconium oxide layer expressed as ZrOₓ satisfies 0.9≦x≦1.4, and the thickness of the first zirconium oxide layer is no less than 1 nm and no more than 5 nm, a stable variable resistance characteristic can be realized

On the other hand, by designing the second variable resistance layer 102b, which has an interface with the semiconductor layer 103, to have an oxygen content atomic percentage that is higher than the oxygen content atomic percentage of the first variable resistance layer, the oxidation of the semiconductor layer 103 can be controlled by the diffusion of oxygen from the second variable resistance layer 102b to the semiconductor layer 103 through heat treatment in the manufacturing process.

Moreover, because a resistance changing operation occurs preferentially in the vicinity of the interface between the first variable resistance layer 102a and the first electrode 101 in response to oxidation and reduction, the vicinity of the interface between the second variable resistance layer 102b and the semiconductor layer 103 does not contribute to a resistance changing operation. For this reason, the oxygen content atomic percentage in the vicinity of the interface between the second variable resistance layer 102b and the semiconductor layer 103 stays constant regardless of a resistance changing operation.

As a result, a preferable diode characteristic can be achieved at the interface between the second variable resistance layer 102b and the semiconductor layer 103.

Here, the semiconductor layer 103 can also be considered to be an electrode which is positioned on the side of the variable resistance layer 102, or the side of the stacked structure of the first variable resistance layer 102a and the second variable resistance layer 102b, opposite the first electrode 101. When this is the case, the variable resistance element is made up from the first electrode 101, the variable resistance layer 102 (or the stacked structure of the first variable resistance layer 102a and the second variable resistance layer 102b), and the semiconductor layer 103.

It is preferable that a noble metal material such as platinum or iridium be used in the first electrode 101 included in the variable resistance element 105. The standard electrode potential of both platinum and iridium is about 1.2 eV. Generally, a standard electrode potential is one indicator of oxidizability. The higher the value, the less oxidizable a material is, and the lower the value, the more oxidizable a material is. Because an oxidation reaction occurs at the variable resistance layer, the greater the difference between the standard electrode potential of the metal included in an electrode and the metal included in a variable resistance layer, the more easily a change in resistance occurs. As the difference becomes smaller, the more difficult it is for a change in resistance to occur in response to an oxidation reaction in the electrode. Accordingly, it is presumed that the high tendency of the variable resistance layer to oxidize at the interface between the electrode and the variable resistance layer will play a large role in a mechanism of the resistance changing phenomenon.

The standard electrode potential of tantalum, at approximately −0.6 eV, is lower than the standard electrode potential of platinum and iridium. Accordingly, oxidation and reduction of the oxygen-deficient tantalum oxide occur in the vicinity of the interface between the first electrode 101 comprising platinum or iridium and the variable resistance layer 102 (the first variable resistance layer 102a), the transfer of oxygen within the variable resistance layer 102 and between the variable resistance layer 102 and the first electrode occurs, and a resistance changing phenomenon occurs.

Materials which have a higher standard electrode potential than tantalum include platinum, iridium, palladium, copper, and tungsten.

Included in the diode element 106, nitrogen-deficient silicon nitride is used in the semiconductor layer 103 and tantalum nitride is used in the second electrode 104. Here, a nitrogen-deficient silicon nitride is a nitride in when a silicon nitride is expressed as SIN_{y} (0<y) and the composition y of nitride N is less than when the silicon nitride is in a stoichiometrically stable state. Because the stoichiometrically stable state is Si₃N₄, a silicon nitride having a composition that satisfies 0<y<1.33 can be said to be a nitrogen-deficient silicon nitride. When tantalum nitride is used, SiN_{y} where 0<y≦0.85 exhibits a semiconductor characteristic, and a Metal-Semiconductor-Metal diode (MSM) can be configured which is capable of flowing a current of, for example, 10 kA/cm², and is capable of turning on and off a current and voltage sufficient enough to cause a change in resistance.

For the nitrogen-deficient silicon nitride formation, a method of sputtering a polysilicon target in a mixed gas atmosphere of argon and nitrogen, in other words, a reactive sputtering method is used. Then, as a typical formation condition, the pressure is set from 0.08 to 2 Pa, the plate temperature is set from 20 to 300 degrees Celsius, the flow rate of nitrogen gas (the flow rate of nitrogen with respect to the total flow rate of argon and nitrogen) is set from 0 to 40%, the direct current power is set from 100 to 1300 W, and the formation time is adjusted so the thickness of the silicon nitride will be from 5 to 20 nm.

Because the work function of tantalum nitride is 4.6 eV, sufficiently higher than the electron affinity of silicon 3.8 eV, a Schottky barrier is formed at the interface between the semiconductor layer 103 and the second electrode 104. Similarly, when the work function of oxygen-deficient tantalum oxide is higher than the electron affinity of silicon, using the oxygen-deficient tantalum oxide causes a Schottky barrier to form at the interface between the variable resistance layer 102 (the second variable resistance layer 102b) and the semiconductor layer 103, and the diode element 106 functions as a bidirectional MSM diode.

Moreover, at the time of resistance change in the variable resistance element, a current flows with a large current density of 10 Ka/cm² or higher. A refractory metal such as tantalum, as well as tantalum nitride or tantalum oxide, have excellent heat resistance properties, and exhibit a characteristic in which stability is maintained even when a current with a large current density is applied. For the reasons described above, examples of preferable electrode materials for the MSM diode include, for example, tantalum, titanium, tungsten, tantalum nitride, titanium nitride, tungsten nitride, and tantalum oxide.

Next, a test on a manufactured the nonvolatile memory element 10 shown in FIG. 1A measuring a current-voltage characteristic (current steering characteristic) achieved by the diode element 106, and the variable resistance characteristic gained by the variable resistance element 105 will be described.

In this test, the nonvolatile memory element 10 was manufactured having dimensions of 50 μm×50 μm in which the first electrode 101 comprises iridium with a thickness of 50 nm, the variable resistance layer 102 comprises oxygen-deficient tantalum oxide (TaO, where x=1.38) with a thickness of 50 nm, the semiconductor layer 103 comprises nitrogen-deficient silicon nitride (SiN_{y} where y=0.30) with a thickness of 15 nm, and the second electrode 104 comprises tantalum nitride with a thickness of 50 nm. It is to be noted that for this test, the variable resistance layer 102 was configured as a single layer in order to confirm the results gained from the nonvolatile memory element 10 having a simplest possible structure.

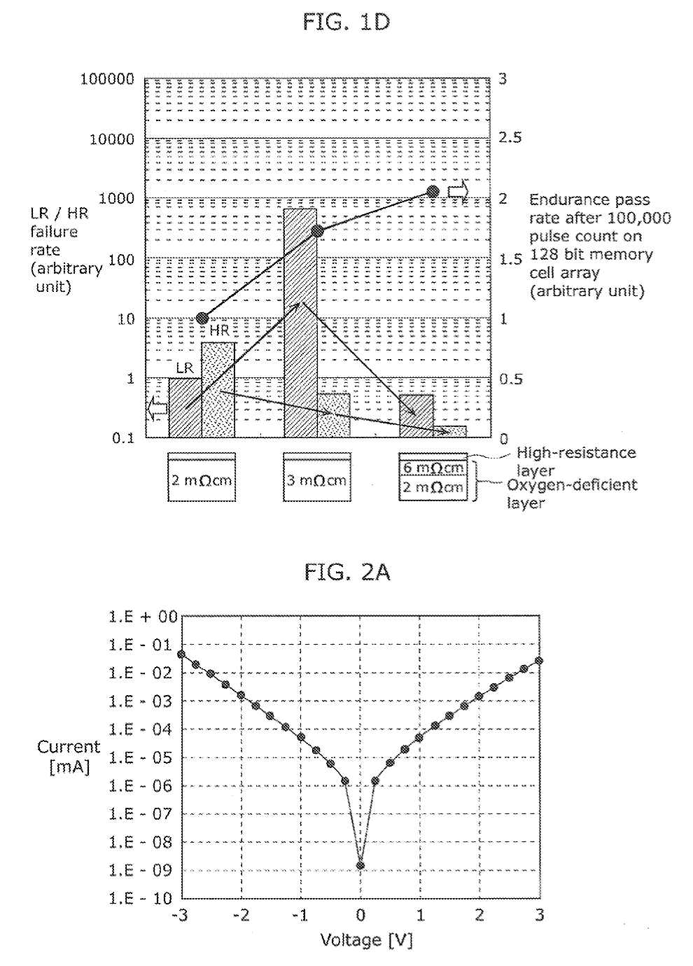

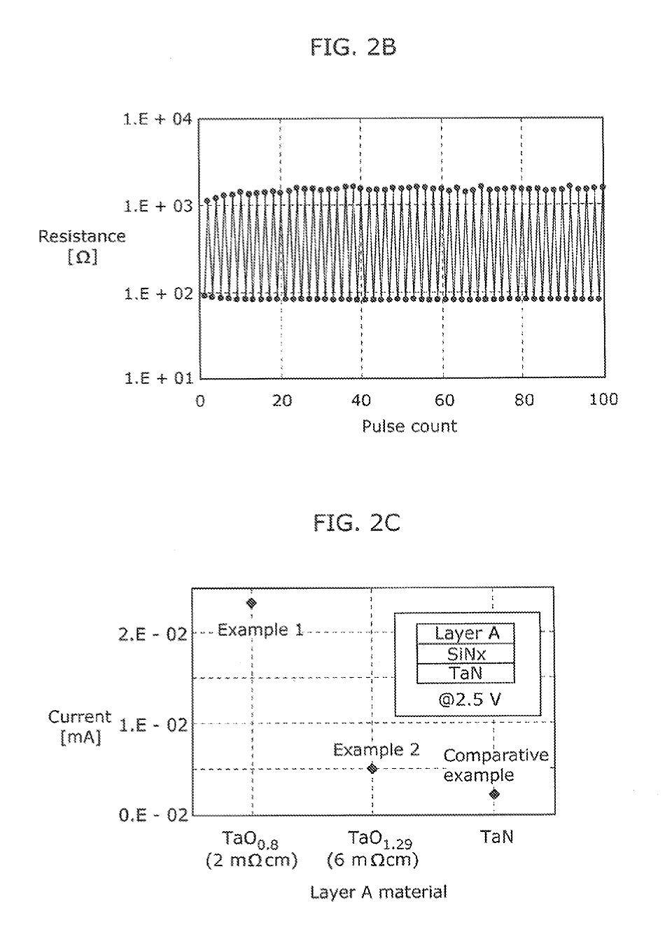

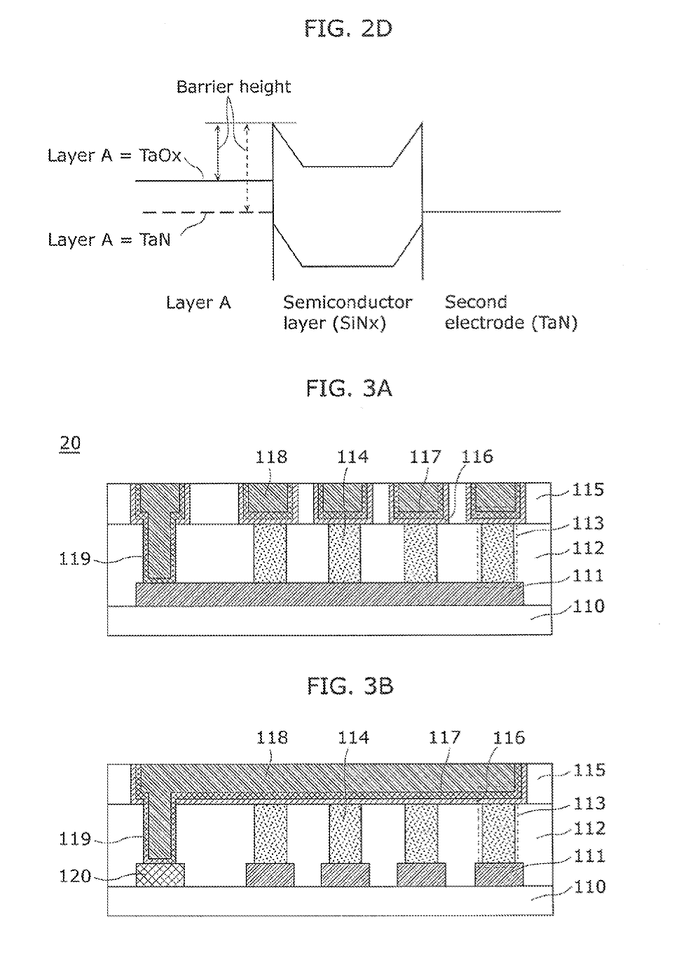

FIG. 2A is a graph showing the current-voltage characteristic of diode element 106 included in the nonvolatile memory element 10 according to the first embodiment.

The current-voltage characteristic shows the result of the flowing current measured at 0.25 V increments as the applied voltage was changed from −3 V to 3V. Here, the applied voltage is the voltage applied to the first electrode 101 with reference to the second electrode 104. In FIG. 2A, the horizontal axis represents the voltage applied to the diode element, and the vertical axis represents the absolute value of the current flowing to the diode element.

As shown in FIG. 2A, the diode element 106, which includes the semiconductor layer comprising nitrogen-deficient silicon nitride (SIN_{y} where y=0.30), and in which the respective electrodes comprise oxygen-deficient tantalum oxide (TaOₓ where x=1.38) and tantalum nitride, was shown to exhibit a nonlinear current-voltage characteristic and to have a current-voltage characteristic in which the diode element 106 functions as a bidirectional diode element that is substantially symmetrical with respect to the polarity of an applied voltage.

Next, FIG. 2B is a graph showing a variable resistance characteristic when electric pulses are applied to the variable resistance element 105 in combination with the diode element 106 within the nonvolatile memory element 10 according to the first embodiment of the present invention are combined.

FIG. 2B shows the measurement result of the resistance value of the variable resistance element while electric pulses were applied between the first electrode 101 and the second electrode 104 so that an electric pulse with a voltage of +2.0 V and an electric pulse with a voltage −1.5 V each having a pulse width of 500 nanoseconds (ns) were alternately applied to the variable resistance element 105. Here, the voltages of the electric pulses were applied to the first electrode 101 with respect to the second electrode 104. In this case, a resistance value of approximately 1 kΩ was reached by applying the electric pulse with a voltage of +2.0 V, and a resistance value of about 100Ω was reached by applying the electric pulse with a voltage of −1.5 V, showing a change approximately by one order of magnitude.

From this measurement result, it was confirmed that in the nonvolatile memory element 10 according to the first embodiment, the variable resistance layer 102 fulfills its primary function as the variable resistance layer included in the variable resistance element 105 as well as fulfilling a function of the electrode included in the diode element 106.

The nonvolatile memory element 10, which has a combination of diode characteristics and variable resistance characteristics, functions as a memory cell having a 1D1R structure. By using the nonvolatile memory element 10 as a memory cell in a crosspoint nonvolatile memory device, a simply configured nonvolatile memory can be implemented in which each memory cell is formed at minimum as a stacked structure of four layers including the electrodes.

Furthermore, the inventors considered a preferable composition for the oxygen-deficient tantalum oxide included in the variable resistance layer 102 from the perspective of the quantity of current (hereinafter also referred to as current carrying capacity) that the diode element 106 is able to pass. As previously stated, because the diode element 106 supplies a large current at the time of resistance change in the variable resistance element 105, it is preferable that the current carrying capacity of the diode element 106 be large.

For this test, in order to compare the current carrying capacity of a plurality of diode elements, three stand alone diode elements were manufactured, each having a three-layered structure made up from a layer A equivalent to the variable resistance layer, a silicon nitride layer equivalent to the semiconductor layer 103, and a tantalum nitride layer equivalent to the second electrode 104. Additionally, a different material was used in the layer A in each of the three stand alone diode elements. The dimensions of the diode elements are 0.5 μm×0.5 μm. After each diode element was confirmed to function as a bidirectional diode element in which the layer A and the second electrode 104 are diode electrodes, a same voltage was applied between the layer A and the tantalum nitride layer, after which the quantity of current flowing to each of the diode elements measured.

FIG. 2C is a graph showing actual measured values of current flowing to the diode element when a voltage of 2.5 V was applied between the electrodes of each diode element. In example 1, the layer A of the diode element comprises tantalum oxide with a composition of TaO_{0.8}. In example 2, the layer A of the diode element comprises tantalum oxide with a composition of TaO_{1.29}. In the comparative example, the layer A of the diode element comprises tantalum nitride. Upon measuring the resistivity of the layer A in example 1, example 2, and the comparative example, the resistivity of TaO_{0.8} was 2 mΩcm, the resistivity of TaO_{1.29} was 6 mΩcm, and the resistivity of TaN was 0.2 mΩcm.

From the graph in FIG. 2C, it can be seen that more current is flowing (in other words the current carrying capacity is larger) through example 1 and example 2, both with a diode element having the layer A comprising oxygen-deficient tantalum oxide, than is flowing through the comparative example with a diode element having the layer A comprising tantalum nitride in the comparative example.

The inventors estimate that the difference between the current carrying capacity of example 1 and example 2 being different from the current carrying capacity of the comparative example is attributed to the difference in materials used in the layer A.

FIG. 2D is a view of an energy band showing an estimate mechanism in which the current carrying capacity of the diode element depends on the electrode material. The height of the barrier that forms at the interface between the layer A and the semiconductor layer is dependent on the work function of the material included in the layer A in such a way that the lower the work function is the lower the barrier height will be.

Accordingly, as is shown in FIG. 2D, the height of the barrier formed at the interface between the layer A and the semiconductor layer is smaller in both example 1 and example 2 in which layer A comprises oxygen-deficient tantalum oxide than in the comparative example in which layer A comprises tantalum nitride. As is shown in FIG. 2C, it is believed that the current carrying capacity of example 1 and example 2 became larger than the comparative example as a result. Because completely oxidized tantalum oxide (Ta₂O₅) has a work function of many accounts it is difficult to simply assess the work function of oxygen-deficient tantalum oxide, however the work function of the oxygen-deficient tantalum oxide TaOₓ can be estimated to be lower than the 4.6 eV work function of tantalum nitride due to the example 1 and the example 2 having exhibited a diode characteristic.

The difference in current carrying capacity between example 1 and example 2, and the comparative example seen in FIG. 2C is thought to be a reflection of the difference in barrier heights of the barrier formed at the interface between the layer A and the semiconductor layer. Along the same line of thought, using a transition metal oxide (for example, titanium oxide which has a work function of 4.0 eV as disclosed in NPL 1: Manabu Seino, Titanium Oxide Physical Properties and Practical Technology, Gihodo Shuppan, or hafnium oxide which has a work function of 2.5 eV as disclosed in PTL 5: Japanese Unexamined Patent Application Publication No. 2000-68061), which has a smaller work function than the work function of TaN, in the layer A is also effective in achieving a diode element having a large current carrying capacity.

In contrast, the difference shown in current carrying capacity between example 1 and example 2 which both include the layer A comprising oxygen-deficient tantalum oxide is thought to be attributed to the difference in resistivity of the layer A. Here, there is a preferable range for the oxygen content atomic percentage of the oxygen-deficient tantalum oxide included in the layer A.

In other words, the oxygen-deficient tantalum oxide included in the layer A is an insulating material when it has an oxygen content atomic percentage that is too high, which causes the current carrying capacity of the diode element to decrease sharply. In the result of the test shown in FIG. 2C, the tantalum oxide TaO_{1.29} of example 2 is an example of a preferable oxygen content atomic percentage at its maximum limit from which a current carrying capacity larger than the comparative example can be obtained.

Moreover, when the oxygen-deficient tantalum oxide included in the layer A has an oxygen content atomic percentage that is too low, a variable resistance characteristic of the variable resistance element is lost. In the result of the test shown in FIG. 2C, the tantalum oxide TaO_{0.80} of example 1 is an example of a preferable oxygen content atomic percentage at its minimum limit from which a variable resistance characteristic can be obtained.

In the explanations of the second through fifth embodiments below, the variable resistance nonvolatile memory device using the nonvolatile memory element 10 according to the first embodiment of the present invention as individual memory cells will be explained.

### Second Embodiment

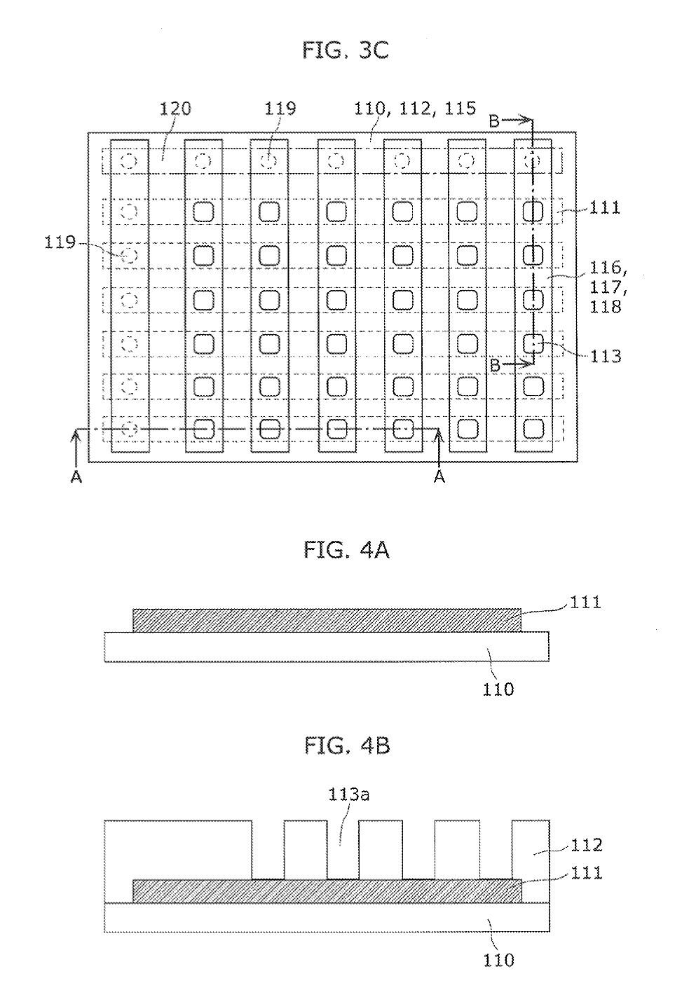

FIG. 3A and FIG. 3B are cross-sectional views showing a configuration of a nonvolatile memory device 20 according to the second embodiment of the present invention. Additionally, FIG. 3C is a plain view showing a configuration of a nonvolatile memory device according to the second embodiment of the present invention. The cross-sectional of a dotted-and-dashed line A shown in FIG. 3C corresponds to FIG. 3A as seen from the direction of the arrows, and the cross-sectional of a dotted-and-dashed line B shown in FIG. 3C corresponds to FIG. 3B as seen from the direction of the arrows. As shown in the plain view of FIG. 3C, according to the second embodiment, a memory cell 113 is formed at the crosspoint of each of a plurality of a first electrode 111 positioned parallel to each other in a striped pattern and each of a plurality of a stacked structure positioned parallel to each other in a striped pattern and made up from a semiconductor layer 116 and a second electrode 117.

The section known as a memory cell array or a memory body part in a general semiconductor memory device is shown as the nonvolatile memory device 20 in FIG. 3A through FIG. 3C. Along with this memory cell array, the nonvolatile memory device 20 may further be provided with a programming circuit for programming the memory cell array. By supplying an electric pulse from the programming circuit to the memory cell array for writing data, the nonvolatile memory device 20 can change the resistance state of a desired the memory cell 113, and by supplying an electric pulse from the programming circuit to the memory cell array for reading data, the nonvolatile memory device 20 can read a resistance state of a desired the memory cell 113.

As shown in FIG. 3A and FIG. 3B, the nonvolatile memory device 20 according to the second embodiment includes a substrate 110 which forms the first electrode 111, a first interlayer insulating layer 112 comprising silicon oxide (with a thickness of 100 to 500 nm) formed on the substrate 110 to cover the first electrode 111, a variable resistance layer 114 and a lead-out contact 119 (both having a diameter of 50 to 300 nm) which are electrically connected to the first electrode 111 and formed in the first interlayer insulating layer 112. The variable resistance layer 114 is formed by penetrating through the first interlayer insulating layer to the first electrode and filling the memory cell hole.

Furthermore, a second interlayer insulating layer 115 comprising silicon oxide is formed on the first interlayer insulating layer 112, the semiconductor layer 116 is formed on the wall and the bottom of a line groove formed on the second interlayer insulating layer 115 to cover the variable resistance layer 114, and a second electrode 117 is formed to cover at least the semiconductor layer 116 that is on the variable resistance layer 114.

The variable resistance element is made up from the first electrode 111 and the variable resistance layer 114, and the diode element is made up from the variable resistance layer 114, the semiconductor layer 116, and the second electrode 117. The memory cell 113 is made up from the variable resistance element and the diode element.

As shown in FIG. 3C, when viewing the nonvolatile memory device 20 from a planar view, a lower layer line and an upper layer line are orthogonal to each other. The lower layer lines are formed in a striped pattern and made up of the first electrode 111. The upper layer lines are formed in a stripe pattern and made up from the semiconductor layer 116, the second electrode 117, and a lead-out line 118. The variable resistance element and the diode element are formed at the crosspoint of the lower layer line and the upper layer line as the memory cell 113. This is how a crosspoint memory cell array is configured. It is to be noted that, while the lower layer line and the upper layer line are orthogonal to each other here, it is not absolutely necessary for them to be orthogonal. It is acceptable if the lower layer line and the upper layer line are disposed so as to cross each other. This is also true for the third through fifth embodiments.

It is to be noted that, as shown in FIG. 3C, the upper layer lines including the lead-out line 118 extend to an area outside the region in which the memory cells 113 are arranged in a matrix, and are connected to a circuit connecting line 120 via the lead-out contact 119 and to a programming circuit (a circuit formed on the substrate 110 and made up of an element generally necessary to a memory circuit such as a DRAM) not shown in the drawings. The lead-out contact 119 and the lead-out line 118 may be formed to be integrated.

By adopting such a configuration, in addition to being able to form the variable resistance layer 114 inside the memory cell hole, a bidirectional diode made up of the semiconductor layer 116 interposed between the variable resistance layer 114 and the second electrode 117 can be formed on top of the memory cell hole. Consequently, a nonvolatile memory device capable of large-capacity storage and high integration can be implemented without disposing a switching element such as a transistor.

Also, compared to a configuration in which a stacked structure comprising a plurality of materials is included inside the memory cell hole, this configuration can easily be manufactured with reduced costs and a reduced number of processes because the variable resistance layer 114 comprising tantalum oxide is formed inside the memory cell hole. Moreover, the thickness of the variable resistance layer 114 which greatly influences memory characteristics becomes easier to control, allowing for a characteristic in which the memory is stable.

In the configuration of the diode element described above, because the contact area of the second electrode 117 and the semiconductor layer 116 is larger than the contact area of the variable resistance layer 114 and the semiconductor layer 116, the electric line of force reaches to the vicinity of the second electrode 117, and the current capacity can be increased. With this, a current that is sufficient enough to stably produce a change in resistance can be secured. Moreover, the second electrode 117 comprising tantalum nitride functions as a barrier layer for the lead-out line 118 comprising copper. It is to be noted that, because the other constituents of the nonvolatile memory device 20 are the same as those in the nonvolatile memory element 10, descriptions with respect to their representative examples will be omitted.

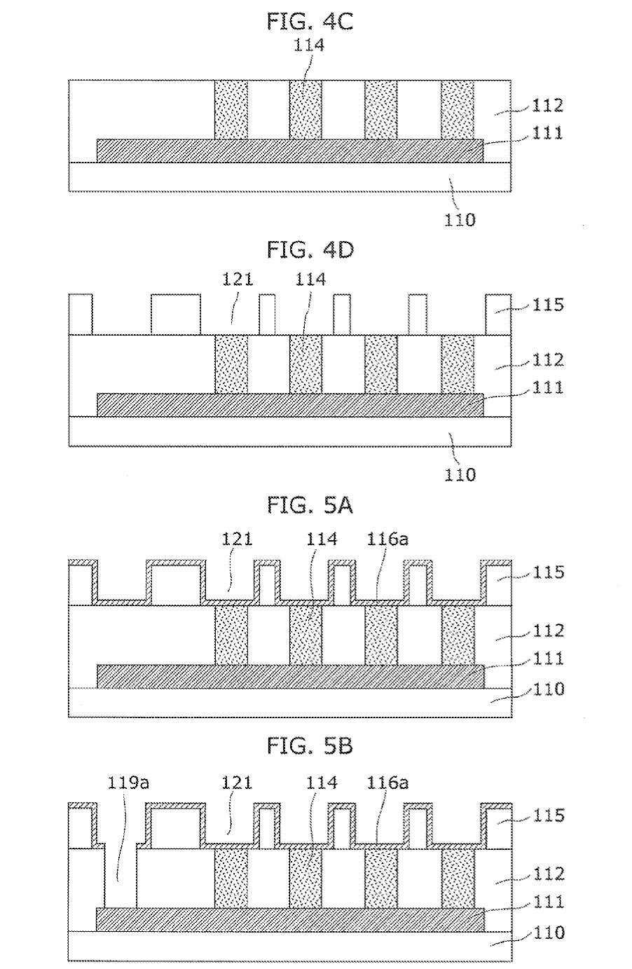

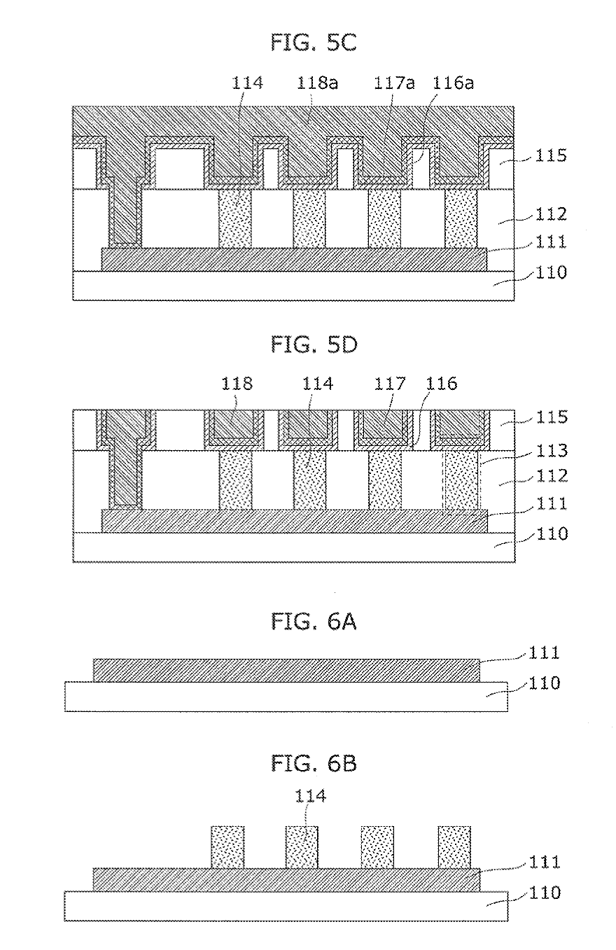

FIG. 4A through FIG. 4D as well as FIG. 5A through FIG. 5D are cross-sectional views showing a method of manufacturing a main component of the nonvolatile memory device 20 according to the second embodiment to form a memory cell using a damascene process. The method of manufacturing will be discussed using each of these drawings.

Firstly, as shown in FIG. 4A, the first electrode 111 comprising a noble metal such as platinum is formed using a desired mask on the substrate 110 having transistors and lower layer lines formed thereon.

Next, as shown in FIG. 4B, after the first interlayer insulating layer 112 comprising silicon oxide is formed on the whole surface covering the first electrode 111, an opening (memory cell hole) 113a is formed penetrating through the first interlayer insulating layer 112 and connecting to the first electrode 111.

Next, as shown in FIG. 4C, the variable resistance layer 114 comprising oxygen-deficient tantalum oxide is formed in the memory cell hole 113a. To form the variable resistance layer 114, a method of sputtering a tantalum target in a mixed gas atmosphere of argon and oxygen, in other words, a reactive sputtering method is used. Oxygen-deficient tantalum oxide is sputtered in the memory cell hole 113a until it is completely filled, then an unnecessary portion of the tantalum oxide on the first interlayer insulating layer 112 is removed by CMP, thus forming the variable resistance layer 114 in the memory sell hole 113a.

Next, as shown in FIG. 4D, a second interlayer insulating layer 115 comprising silicon oxide (with a thickness of 100 to 400 nm) is formed on the first interlayer insulating layer 112, and a line groove 121 to be filled with the lead-out line 118 and such later on is patterned with a desired mask. As a result, the variable resistance layer 114 is exposed at the bottom of the line groove 121.

Next, as shown in FIG. 5A, a semiconductor membrane 116a comprising nitrogen-deficient silicon nitride is formed to cover the whole surface, including the line groove 121 exposing the variable resistance layer 114. The semiconductor membrane 116a is formed by reactive sputtering in which a silicon target is sputtered in a mixed gas atmosphere of argon and nitrogen. The nitrogen content percentage is 20 to 40 atm %.

Next, as shown in FIG. 5B, an opening (contact hole) 119a is formed penetrating through the semiconductor membrane 116a, which is formed between the first interlayer insulating layer 112 and the line groove 121, and connecting to the first electrode 111.

Next, as shown in 5C, a second electrode layer 117a comprising tantalum nitride is formed on the whole surface covering the semiconductor membrane 116a and a contact hole 119a above the line groove 121 and the second interlayer insulating layer 115 is formed, and a lead-out line layer 118a comprising copper is formed to completely fill the line groove 121 and the contact hole 119a.

Lastly, as shown in FIG. 5D, unnecessary portions of the copper, tantalum nitride, and nitrogen-deficient silicon nitride on the second Interlayer insulating layer 115 are removed by CMP, and the semiconductor layer 116 comprising nitrogen-deficient silicon nitride, the second electrode 117 comprising tantalum nitride, and the lead-out line 118 comprising copper are formed in the line groove 121. At the same time, the second electrode 117 comprising tantalum nitride which plays a role as a barrier layer and the lead-out line 118 comprising copper are formed in the contact hole 119a.

By adopting such a method of manufacturing, the variable resistance element is made up from the first electrode 111 and the variable resistance layer 114, a resistance changing operation is caused at the interface area of the first electrode 111, and because a polarity with which the resistance changes is stabilized, a characteristic in which memory is stable can be achieved.

Moreover, the diode element is made up from the variable resistance layer 114, the semiconductor layer 116, and the second electrode 117, and because the bidirectional diode can be formed on the upper part of the memory cell, it is not necessary to dispose a switching element such as a transistor on the substrate. Accordingly, the variable resistance nonvolatile memory device capable of large-capacity storage and high integration having a filling hole structure suitable for miniaturization can be implemented.

Moreover, with the nonvolatile memory device 20 according to the second embodiment, because the variable resistance layer 114 is formed in the memory cell hole 113a, the memory cell 113 can be easily formed by an etching process, and miniaturization is also possible.

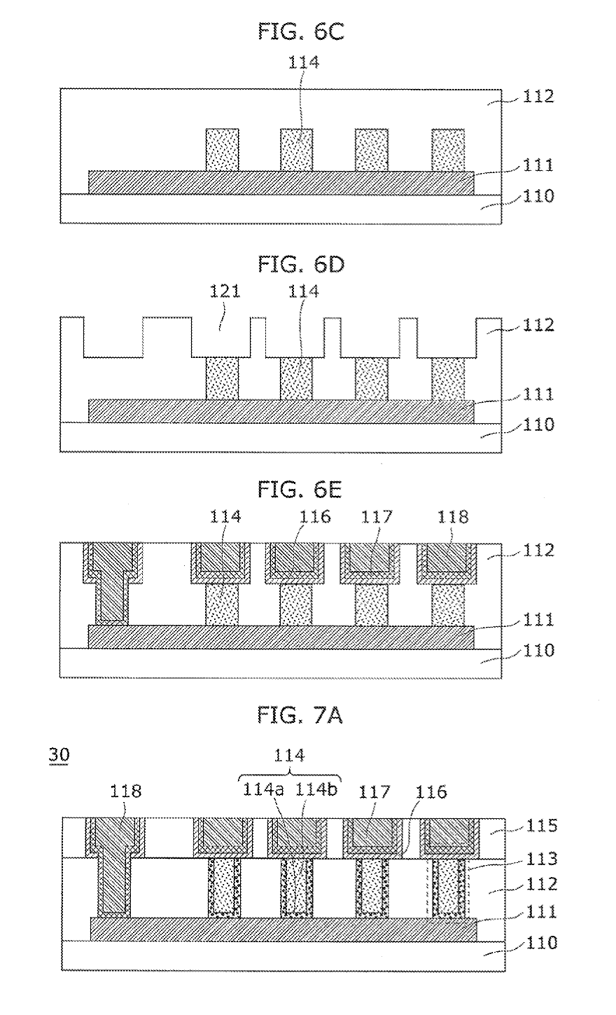

FIG. 6A through FIG. 6E are cross-sectional views showing a method of manufacturing for forming the memory cell using this etching process. The method of manufacturing will be discussed using each of these drawings.

Firstly, as shown in FIG. 6A, the first electrode 111 comprising a noble metal such as platinum is formed using a desired mask on the substrate 110 having transistors and lower layer lines formed thereon.

Next, as shown in FIG. 6B, the variable resistance layer 114 is formed in a pillar shape on the first electrode 111 using an etching process with a desired mask. The variable resistance layer 114 is formed in a memory cell region on the first electrode 111.

Next, as shown in FIG. 6C, the first interlayer insulating layer 112 comprising silicon oxide is formed on the whole surface covering the first electrode 111 and the variable resistance layer 114.

Next, as shown in FIG. 6D, on the first interlayer insulating layer 112, the line groove 121 to be filled with the lead-out line 118 and such later on is sputtered with a desired mask. As a result, the variable resistance layer 114 is exposed at the bottom of the line groove 121.

It is to be noted that the methods of manufacturing used in the drawings after FIG. 6D are the same as those from FIG. 5A to FIG. 5D, and as such their explanations will be omitted.

In accordance with the methods of manufacturing previously described (in FIG. 4A through FIG. 4D), when filling and forming a variable resistance layer in a memory cell hole having a high aspect ratio (opening is small and deep), there is a concern that the opening on the upper part of the memory cell hole will become clogged due to the variable resistance material being formed in an overhung shape before the memory cell hole is sufficiently filled with the variable resistance layer.

In response to this concern, with the method of manufacturing by etching described afterwards (in FIG. 6A through FIG. 6D), there is no concern of the opening on the upper part of the memory cell hole being clogged shut, and memory cells with a high aspect ratio can be relatively easily formed.

### Third Embodiment

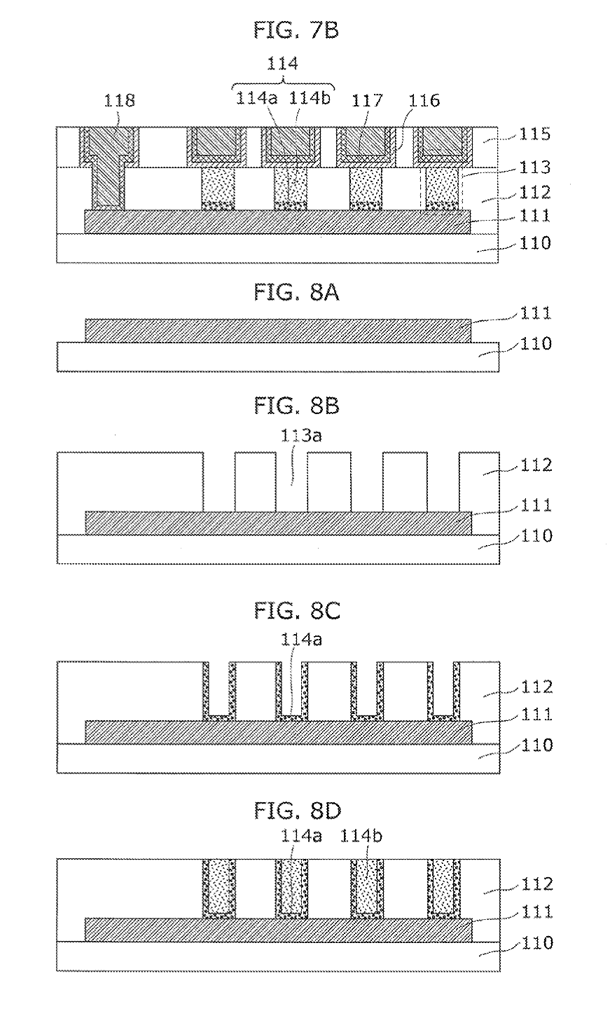

FIG. 7A and FIG. 7B are cross-sectional views showing a configuration of a nonvolatile memory device 30 according to the third embodiment of the present invention. The structure of the nonvolatile memory device 30 according to the third embodiment of the present invention is nearly identical to the structure of the nonvolatile memory device according to the second embodiment of the present invention. The variable resistance layer 114 comprising the memory cell is made up of a stacked structure of two layers including the first variable resistance layer 114a and the second variable resistance layer 114b, and the first variable resistance layer 114a is connected to the first electrode 111. The nonvolatile memory device 30 is characterized by the first variable resistance layer 114a having an oxygen content atomic percentage that is higher than the oxygen content atomic percentage of the second variable resistance layer 114b.

FIG. 7A is view of a composition of the nonvolatile memory device 30 according to the present invention when the memory cell is formed using a damascene process, while FIG. 7B shows the composition when the memory cell is formed using an etching process.

In this composition, the variable resistance element is made up from the first electrode 111 and the variable resistance layer 114 which includes the first variable resistance layer 114a and the second variable resistance layer 114b. Here, by designing the first variable resistance layer 114a to have a high oxygen content atomic percentage in the vicinity of its interface with the first electrode 111, a change in resistance in response to oxidation and reduction at the interface of the first electrode 111 can occur more easily. Accordingly, the memory cell having a preferable variable resistance characteristic in which low voltage programming can be achieved.

Moreover, because oxidation and reduction occurs in the first variable resistance layer 114a which has a high oxygen content atomic percentage in the vicinity of the first electrode 111, there is no change in the oxygen concentration of the second variable resistance layer 114b which has a low oxygen content atomic percentage in the vicinity of its interface with the semiconductor layer 116. Consequently, a stable diode characteristic can be achieved regardless of a resistance changing operation at the interface between the variable resistance layer 114 and the semiconductor layer 116.

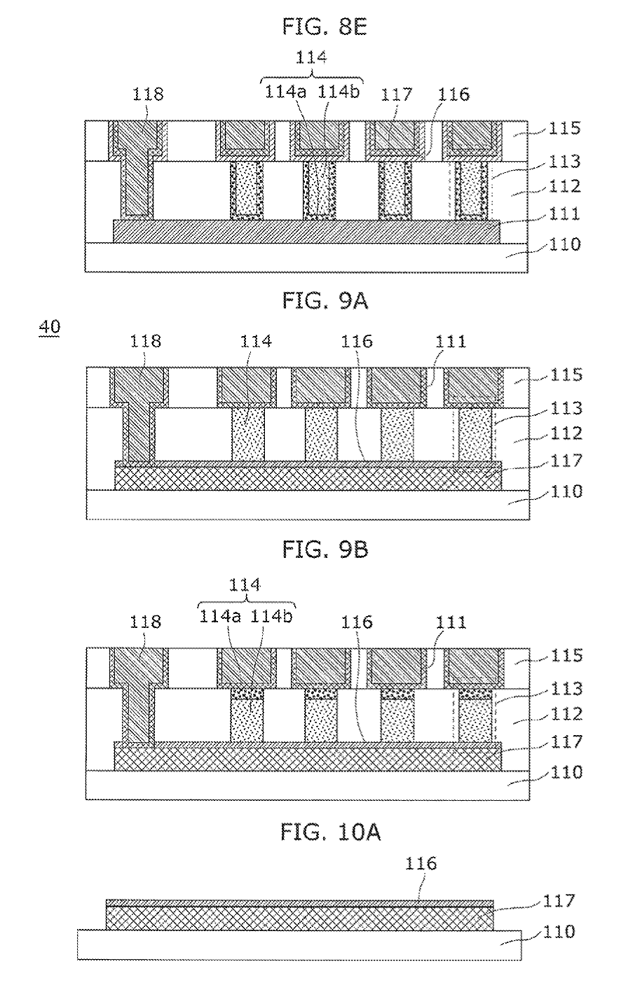

FIG. 8A through FIG. BE are cross-sectional views showing a method of manufacturing a main component of the nonvolatile memory device 30 according to the third embodiment shown in FIG. 7A using a damascene process. The method of manufacturing will be discussed using each of these drawings.

Firstly, as shown in FIG. 8A, the first electrode 111 comprising a noble metal such as platinum is formed using a desired mask on the substrate 110 having transistors and lower layer lines formed thereon.

Next, as shown in FIG. 86, after the first interlayer insulating layer 112 comprising silicon oxide is formed on the whole surface covering the first electrode 111, the opening (memory cell hole) 113a is formed penetrating through the first interlayer insulating layer 112 and connecting to the first electrode 111.

Next, as shown in FIG. 8C, tantalum oxide is formed on the bottom and wall of the memory cell hole 113a as well as on the first interlayer insulating layer 112 by reactive sputtering in which a tantalum target is sputtered in a mixed gas atmosphere of argon and oxygen. Afterwards, an unnecessary portion of tantalum oxide formed on the first interlayer insulating layer 112 is removed by CMP. As a result, the first variable resistance layer 114a is formed on the bottom and wall of the memory cell hole 113a. When using reactive sputtering, an oxygen content atomic percentage can be increased by increasing the flow rate of oxygen at the time of forming. Here, sputtering is performed at a power of 1.6 kW while flowing argon gas at 34 sccm and oxygen gas at 24 sccm, thereby forming the first variable resistance layer 114a having an oxygen content atomic percentage of approximately 71 atm %. Moreover, the first variable resistance layer 114a may be formed using a target of Ta₂O₅.

Next, as shown in FIG. 8D, tantalum oxide for the second variable resistance layer 114b is formed inside the memory cell hole, on the surface of which the first variable resistance layer 114a is formed. The second variable resistance layer 114b has an oxygen content atomic percentage that is lower than the first variable resistance layer 114a. Similar to the first variable resistance layer 114a, the tantalum oxide is also formed by reactive sputtering. Sputtering is performed until the inside of the memory cell hole 113a is completely full. Afterwards, an unnecessary portion of tantalum oxide formed on the first interlayer insulating layer 112 is removed by CMP. As a result, the second variable resistance layer 114b is formed inside the memory cell hole 113a. Here, sputtering is performed at a power of 1.6 kW while flowing argon gas at 34 sccm and oxygen gas at 20.5 sccm, thereby forming the second variable resistance layer 114b having an oxygen content atomic percentage of approximately 58 atm %.

In the process shown in FIG. 8C and FIG. 8D, after the first variable resistance layer 114a is firstly formed on the bottom and wall of the memory cell hole 113a, the second variable resistance layer 114b is filled and formed in the memory cell hole 113a. However, a process is also acceptable in which the first variable resistance layer 114a and the second variable resistance layer 114b are continuously formed then filled into the memory cell hole 113a, whereafter an unnecessary portion of the tantalum oxide on the first interlayer insulating layer 112 is removed by CMP, thus forming the variable resistance layer 114 in the memory cell hole 113a.

With the processes described above and shown in FIG. 8C and FIG. 8D, the variable resistance layer 114 is deposited on the entire surface of the wafer including inside the already formed memory cell hole 113a. An unnecessary portion of the variable resistance layer 114 outside the memory cell hole 113a is subsequently removed by CMP, thereby completing the patterning of the variable resistance layer 114. Therefore, because it is not necessary to perform an etching process, The variable resistance layer 114 can be formed while in principle avoiding concerns associated with dry etching such as damage resulting from a reaction to the etching gas used to etch the variable resistance layer 114, oxygen reduction damage incurred during the etching process, and charge-up damage incurred during the etching process.

It is to be noted that the methods of manufacturing used in the drawings after FIG. 8D are the same as those in FIG. 4D and from FIG. 5A to FIG. 5D, and as such their explanations will be omitted.

By adopting such a method of manufacturing, in the memory cell 113, the variable resistance element is made up from the first electrode 111, the first variable resistance layer 114a, and the second variable resistance layer 114b, and a change in resistance can be caused with certainty at the interface area of the first electrode 111. Furthermore, because the second variable resistance layer 114b is formed having a low oxygen content atomic percentage in the vicinity of its interface with the semiconductor layer 116, the oxidation of the semiconductor layer 116 can be controlled through heat treatment in the manufacturing process. As a result, a stable variable resistance characteristic and diode characteristic can be achieved. Accordingly, the variable resistance nonvolatile memory device capable of large-capacity storage and high integration and having a filling hole suitable for miniaturization can be manufactured.

### Fourth Embodiment

FIG. 9A and FIG. 9B are views explaining a configuration of a nonvolatile memory device 40 according to the second embodiment of the present invention. The configuration of the nonvolatile memory device 40 according to the fourth embodiment is almost the same as the configuration of the nonvolatile memory device 20 according to the second embodiment of the present invention flipped vertically, and is characterized by the second electrode 117 and the semiconductor layer 116 being formed beneath the memory cell 113.

By adopting such a configuration, the semiconductor layer 116 can be formed on the surface of the second electrode 117 which is smooth in comparison to the bottom surface of the line groove connected to the memory cell 113. As a result, even if the thickness of the semiconductor layer 116 is made thin in order to increase a current density that can be flowed to the diode element, a precise and continuous film can be achieved. Furthermore, with this configuration, because the semiconductor layer 116 is horizontally shaped larger than the memory cell 113, the second electrode 117 and the variable resistance layer 114 are connected, thereby preventing a leak from occurring. Furthermore, the semiconductor layer 116 is formed in such a way that it is disposed outside of variable resistance layer 114 as well, so that the electric pulses flowing to the diode element spread outside the area of the variable resistance layer. As a result, a diode element having a large current carrying capacity compared to conventional diodes and having few variations in its characteristics can be achieved.

Furthermore, in FIG. 9B, similar to the third embodiment, the variable resistance layer 114 is made up of a stacked structure of two layers including the first variable resistance layer 114a and the second variable resistance layer 114b, and the first variable resistance layer 114a is connected to the first electrode 111. Also, the nonvolatile memory device 40 is characterized by the first variable resistance layer 114a having an oxygen content atomic percentage that is higher than the oxygen content atomic percentage of the second variable resistance layer 114b. With this configuration, by designing the variable resistance layer 114 to have a high oxygen content atomic percentage in the vicinity of its interface with the first electrode 111, a change in resistance in response to oxidation and reduction at the interface of first electrode can occur more easily, and the memory cell having a preferable variable resistance characteristic in which low voltage programming can be achieved.

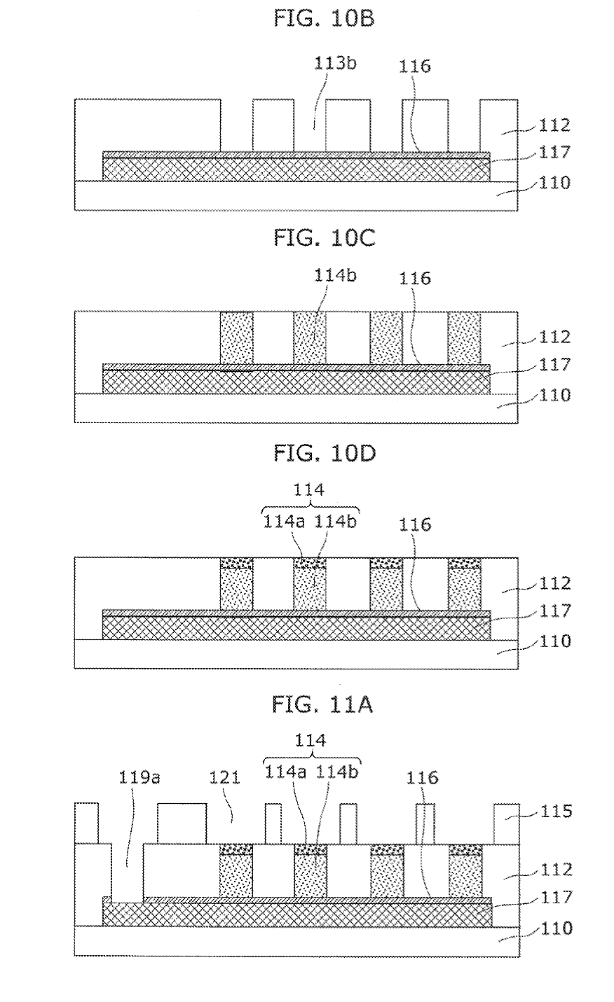

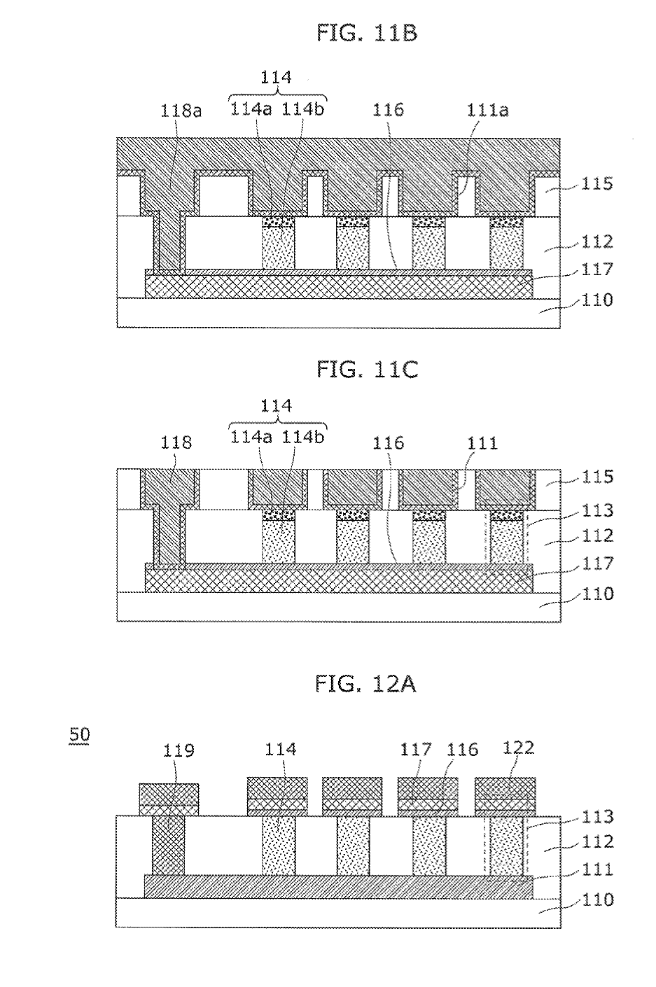

FIG. 10A through FIG. 10D as well as FIG. 11A through FIG. 11C are cross-sectional views showing a method of manufacturing a main component of the nonvolatile memory device 40 according to the fourth embodiment shown in FIG. 9B to form a memory cell using a damascene process. The method of manufacturing will be discussed using each of these drawings.

Firstly, as shown in FIG. 10A, the second electrode 117 comprising tantalum nitride and the semiconductor layer 116 comprising nitrogen-deficient silicon nitride are formed using a desired mask on the substrate 110 having transistors and lower layer lines formed thereon. Because the second electrode 117 is desired to function as a line (having low resistivity) as well, the second electrode 117 may also be made up from a stacked structure in which a lower layer comprises a material having low resistivity such as copper and an upper layer comprises tantalum nitride.

Next, as shown in FIG. 10B, after the first interlayer insulating layer 112 comprising silicon oxide is formed on the whole surface covering the second electrode 116 and the semiconductor layer 116, an opening (memory cell hole) 113b is formed penetrating through the first interlayer insulating layer 112 and connecting to the semiconductor layer 116.

Next, as shown in FIG. 10C, the second variable resistance layer 114b comprising tantalum oxide, which has a low oxygen content atomic percentage, is formed in the memory cell hole 113b. Reactive sputtering in which a tantalum target is sputtered in a mixed gas atmosphere of argon and oxygen is used to form the second variable resistance layer 114b. Sputtering is performed until the inside of the memory cell hole 113b is completely full. Afterwards, an unnecessary portion of tantalum oxide formed on the first interlayer insulating layer 112 is removed by CMP. As a result, the second variable resistance layer 114b is formed inside the memory cell hole 113b.

Next, as shown in FIG. 10D, a portion of the surface layer of the second variable resistance layer 114b is oxidized through a plasma oxidation process or a thermal oxidation process, thus forming the first variable resistance layer 114a having a high oxygen content atomic percentage.

Next, as shown in FIG. 11A, a second interlayer insulating layer 115 comprising silicon oxide (with a thickness of 100 to 300 nm) is formed on the first interlayer insulating layer 112, and a line groove 121 to be filled with the lead-out line 118 and such later on is sputtered with a desired mask. As a result, the first variable resistance layer 114a is exposed at the bottom of the line groove 121. It is to be noted that, as a substitute for the process described above, after the line groove 121 is formed, the first variable resistance layer 114a having a high oxygen content atomic percentage may be formed by oxidizing a portion of the surface layer of the second variable resistance layer 114b through a plasma oxidation process or a thermal oxidation process. Furthermore, the opening (contact hole) 119a is formed penetrating through the semiconductor layer 116 and the first interlayer insulating layer 112, connecting to the second electrode 117.

Next, as shown in FIG. 11B, a first electrode layer 111a comprising a noble metal such as platinum is formed on the whole surface covering above the line groove 121 and the second interlayer insulating layer 115 and the inside the contact hole 119a, and the lead-out line layer 118a comprising, for instance, copper, is further formed to completely fill the line groove 121 and the contact hole 119a.

Lastly, as shown in FIG. 11C, an unnecessary portion of the noble metal such as copper and platinum formed on the second interlayer insulating layer 115 is removed by CMP or etching. As a result, the first electrode 111 and the lead-out line 118 are formed inside the line groove 121 and the contact hole 119a.

By adopting such a method of manufacturing, the diode element is made up from the second electrode 117, the semiconductor layer 116, and the variable resistance layer 114, and the bidirectional diode can be formed on the bottom of the memory cell. Moreover, the variable resistance element is made up from the variable resistance layer 114 and the first electrode 111. The first variable resistance layer 114a having a high oxygen content atomic percentage can be formed with a high degree of controllability with respect to the thickness through a plasma oxidation process or a thermal oxidation process on the surface of the variable resistance layer 114 filled and formed in the memory cell hole 113a. As a result, a change in resistance can be caused with certainty at the interface area of the first electrode 111, and because a polarity with which the resistance changes is stabilized, a characteristic in which memory is stable can be achieved. Accordingly, the variable resistance nonvolatile memory device capable of large-capacity storage and high integration and having a filling hole suitable for miniaturization can be manufactured.

### Fifth Embodiment

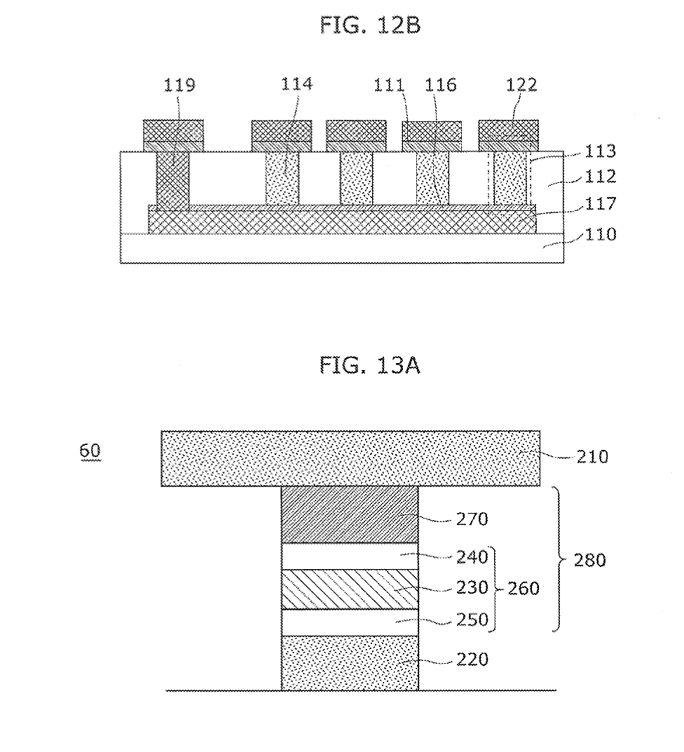

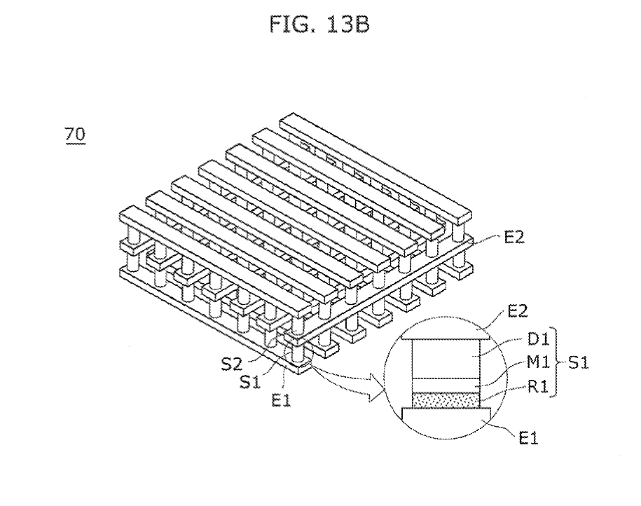

FIG. 12A and FIG. 12B are cross-sectional views showing a configuration of a variable resistance nonvolatile memory device 50 according to the fifth embodiment of the present invention.

In the second, third, and fourth embodiments of the present invention, the electrode on the top of the memory cell 113 is filled and formed in the second interlayer insulating layer 115 using a damascene process, but in nonvolatile memory device 50 according to the fifth embodiment is characterized by the semiconductor layer 116 and the second electrode 117 formed on the top of the memory cell 113 and the first electrode 111 being formed using an etching process.

This kind of configuration is effecting when using a material for the semiconductor layer 116, the second electrode 117, or the first electrode 111 in which forming by CMP after the material is filled is problematic, for example when using SIC or ZnO in the semiconductor layer, or a noble metal such as Pt in an electrode material. Moreover, because the electrode formed on the upper part of the memory cell 113 is desired to function as a line (having low resistivity) as well, an upper layer line layer 122 comprising a low resistivity material such as copper or tungsten may be formed on that electrode.

The description regarding the method of forming the electrode and the upper layer line layer 122 above the first interlayer insulating layer 112 using an etching process shall be omitted because the electrode and the upper layer line layer 122 can easily be formed through a general exposure process and etching process.

As is clearly shown from the preceding descriptions of the first through fifth embodiments, a technical achievement of the present invention, in which the variable resistance nonvolatile memory element made up from the variable resistance element and the diode element electrically connected in a series, includes the discovery of a preferable configuration in which the variable resistance layer, provided as one layer in the conventional configuration of the variable resistance element, also performs a role as an electrode of the diode element, and based on the discover, the variable resistance nonvolatile memory element is implemented as, at the least, a stacked structure of four layers including the electrode.

It is to be noted that, according to the first through fifth embodiments described above, the transition metal oxide included in the variable resistance layer was described as being tantalum oxide, hafnium oxide, or zirconium oxide. However, as a primary variable resistance layer performing a change in resistance, the transition metal oxide layer interposed between the upper and lower electrodes may be an oxide layer comprising tantalum, hafnium, or zirconium, for example, and may also comprise a trace amount of another chemical element. Intentionally including another chemical element in order to finely adjust the resistance value is also possible and doing so is also intended to be included within the scope of the present invention. For example, when nitrogen is added to the variable resistance layer, the resistance value of the variable resistance layer increases, and the responsiveness to a change in resistance can be improved.

Therefore, regarding a variable resistance element having a variable resistance layer comprising an oxygen-deficient transition metal oxide M, when the variable resistance layer is configured of a first region comprising a first oxygen-deficient transition metal oxide having a composition represented by MOₓ (where 0<x<s when the stoichiometric composition of a transition metal oxide is represented by MOₛ), and a second region comprising a second oxygen-deficient transition metal oxide having a composition represented by MO_{y} (where x<y), the respective transition metal oxides included in the first region and the second region shall not be precluded from comprising a predetermined impurity (for example, an additive for adjusting the resistance value).

Moreover, when forming a resistive film by sputtering, it goes without saying that an unintended trace amount of an element being mixed into the resistive film as a result of residual gas or gas emission from the walls of the vacuum chamber also falls within scope of the present invention.

Moreover, a number of variations on the configuration of the variable resistance nonvolatile memory device using the variable resistance nonvolatile memory element according to the second through fifth embodiments as a memory cell were disclosed in their respective embodiments, however, these embodiments are examples and the present invention is not limited to these embodiments.

As long as they do not depart from the essence of the present invention, that is, the concept of the variable resistance layer also performing a role as an electrode of the diode element, various modifications to the present embodiment which may be conceived by those skilled in the art are intended to be included within the scope of this invention.

### INDUSTRIAL APPLICABILITY

The present invention provides a structure of a variable resistance nonvolatile memory device suitable for miniaturization and a method of manufacturing the same, in which a high-capacity nonvolatile memory can be achieved. Accordingly, the present invention is useful in a variety of electronic fields which use nonvolatile memory devices.

### REFERENCE SIGNS LIST

10 nonvolatile memory element
20, 30, 40, 50 nonvolatile memory device
60 nonvolatile semiconductor memory device
70 resistive memory element
101 first electrode
102 variable resistance layer
102a first variable resistance layer (first tantalum oxide layer)
102b second variable resistance layer (second tantalum oxide layer)
102c third variable resistance layer (third tantalum oxide layer)
103 semiconductor layer
104 second electrode
105 variable resistance element
106 diode element
110 substrate
111 first electrode
111a first electrode layer
112 first interlayer insulating layer
113 memory cell
113a, 113b memory cell hole
114 variable resistance layer
114a first variable resistance layer
114b second variable resistance layer
115 second interlayer insulating layer
116 semiconductor layer
116a semiconductor membrane
117 second electrode
117a second electrode layer
118 lead-out line
118a lead-out line layer
119 lead-out contact
119a contact hole
120 circuit connecting line
121 line groove
122 upper layer line layer
210 bit line
220 word line
230 variable resistance layer
240 upper electrode
250 lower electrode
260 variable resistance element
270 nonlinear element
280 memory cell
D1 first diode
E1 first electrode
E2 second electrode
M1 intermediate electrode
R1 variable resistance layer
S1 first structure
S2 second structure

1-14. (canceled)

15. A variable resistance nonvolatile memory element comprising:
a first electrode comprising a material including a metal as a main component;
a variable resistance layer disposed adjacent to said first electrode in the thickness direction and having a resistance value that changes reversibly in response to predetermined electric pulses having different polarities being applied;
a semiconductor layer disposed adjacent to said variable resistance layer in the thickness direction and comprising a material including a nitrogen-deficient silicon nitride as a main component; and
a second electrode disposed adjacent to said semiconductor layer in the thickness direction,
wherein said variable resistance layer has a stacked structure including a first variable resistance layer, a third variable resistance layer, and a second variable resistance layer, the first variable resistance layer being adjacent to said first electrode, and the third variable resistance layer being interposed between the first variable resistance layer and the second variable resistance layer, and each layer comprising a material having an oxygen-deficient transition metal oxide as a main component, the oxygen-deficient transition metal oxide included in the first variable resistance layer having a higher oxygen content atomic percentage than the oxygen content atomic percentage of the oxygen-deficient transition metal oxide included in the second variable resistance layer, and the oxygen-deficient transition metal oxide included in the third variable resistance layer having an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer, and
a stacked structure including said variable resistance layer, said semiconductor layer, and said second electrode functions as a bidirectional diode.

16. The variable resistance nonvolatile memory element according to claim 15, wherein said variable resistance layer comprises a material including an oxygen-deficient tantalum oxide as a main component.

17. The variable resistance nonvolatile memory element according to claim 16, wherein the oxygen-deficient tantalum oxide included in the second variable resistance layer has a composition represented by TaO_{y} where 0<y<1.29.

18. The variable resistance nonvolatile memory element according to claim 17, wherein the oxygen-deficient tantalum oxide included in the second variable resistance layer has a composition represented by TaO_{y} where 0.8<y<1.29.

19. The variable resistance nonvolatile memory element according to claim 15, wherein a standard electrode potential of the metal included in said first electrode is higher than a standard electrode potential of a transition metal included in the first variable resistance layer.

20. The variable resistance nonvolatile memory element according to claim 19, wherein said first electrode comprises one of metals including platinum, iridium, palladium, copper, and tungsten, a composite of the metals, or an alloy of the metals, and said second electrode comprises one of metals including tantalum nitride, titanium nitride, and tungsten, or a composite of the metals.

21. The variable resistance nonvolatile memory element according to claim 15, wherein the second variable resistance layer uses a material having a work function that is higher than a work function of said semiconductor layer.

22. The variable resistance nonvolatile memory element according to claim 20, wherein said second electrode uses a material having a work function that is higher than a work function of said semiconductor layer.

23. A variable resistance nonvolatile memory device comprising:
a plurality of first lines extending in a first direction;
a plurality of second lines extending in a second direction which intersects the first direction; and
a plurality of memory cells each positioned at a corresponding one of crosspoints of said first lines and said second lines,
wherein each of said memory cells includes said variable resistance nonvolatile memory element according to claim 15,
said first lines include said first electrodes of said variable resistance nonvolatile memory elements that are connected to each other, and
said second lines include said second electrodes of said variable resistance nonvolatile memory elements that are connected to each other.

24. A method of manufacturing a variable resistance nonvolatile memory element, said method comprising:
forming a first electrode;
forming an interlayer insulating layer on the first electrode;
forming an opening in a memory cell region on the interlayer insulating layer extending through to the first electrode;
forming, inside the opening, a variable resistance layer having a stacked structure including a first variable resistance layer, a third variable resistance layer, and a second variable resistance layer, the first variable resistance layer being adjacent to the first electrode, and the third variable resistance layer being interposed between the first variable resistance layer and the second variable resistance layer, and each layer comprising a material having an oxygen-deficient transition metal oxide as a main component, the oxygen-deficient transition metal oxide included in the first variable resistance layer having a higher oxygen content atomic percentage than the oxygen content atomic percentage of the oxygen-deficient transition metal oxide included in the second variable resistance layer, and the oxygen-deficient transition metal oxide included in the third variable resistance layer having an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer;
forming a semiconductor layer covering the variable resistance layer; and
forming a second electrode covering the semiconductor layer at least at a portion above the variable resistance layer.

25. A method of manufacturing a variable resistance nonvolatile memory element, said method comprising:
forming a first electrode;
forming a variable resistance layer in a memory cell region on the first electrode, the variable resistance layer having a stacked structure including a first variable resistance layer, a third variable resistance layer, and a second variable resistance layer, the first variable resistance layer being adjacent to the first electrode, and the third variable resistance layer being interposed between the first variable resistance layer and the second variable resistance layer, and each layer comprising a material having an oxygen-deficient transition metal oxide as a main component, the oxygen-deficient transition metal oxide included in the first variable resistance layer having a higher oxygen content atomic percentage than the oxygen content atomic percentage of the oxygen-deficient transition metal oxide included in the second variable resistance layer, and the oxygen-deficient transition metal oxide included in the third variable resistance layer having an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer;
forming an interlayer insulating layer covering the first electrode and the variable resistance layer;
forming a groove in a surface of the interlayer insulating layer that extends depthwise through to the variable resistance layer;
forming a semiconductor layer covering the variable resistance layer exposed from the groove; and
forming a second electrode covering the semiconductor layer at least at a portion above the variable resistance layer.

26. A method of manufacturing a variable resistance nonvolatile memory element, said method comprising:
forming a second electrode;
forming a semiconductor layer on the second electrode;
forming an interlayer insulating layer covering the second electrode and the semiconductor layer;
forming an opening in a memory cell region on the interlayer insulating layer extending through to the semiconductor layer;
forming, inside the opening, a variable resistance layer having a stacked structure including a second variable resistance layer, a third variable resistance layer, and a first variable resistance layer, the second variable resistance layer being connected to the semiconductor layer, and the third variable resistance layer being interposed between the first variable resistance layer and the second variable resistance layer, and each layer comprising a material having an oxygen-deficient transition metal oxide as a main component, the oxygen-deficient transition metal oxide included in the first variable resistance layer having a higher oxygen content atomic percentage than the oxygen content atomic percentage of the oxygen-deficient transition metal oxide included in the second variable resistance layer, and the oxygen-deficient transition metal oxide included in the third variable resistance layer having an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer; and
forming a first electrode covering the variable resistance layer.

27. A method of manufacturing a variable resistance nonvolatile memory element, said method comprising:
forming a second electrode;
forming a semiconductor layer on the second electrode;
forming a variable resistance layer in a memory cell region on the semiconductor layer, the variable resistance layer having astacked structure including a second variable resistance layer, a third variable resistance layer, and a first variable resistance layer, the second variable resistance layer being connected to the semiconductor layer, and the third variable resistance layer being interposed between the first variable resistance layer and the second variable resistance layer, and each layer comprising a material having an oxygen-deficient transition metal oxide as a main component, the oxygen-deficient transition metal oxide included in the first variable resistance layer having a higher oxygen content atomic percentage than the oxygen content atomic percentage of the oxygen-deficient transition metal oxide included in the second variable resistance layer, and the oxygen-deficient transition metal oxide included in the third variable resistance layer having an oxygen content atomic percentage that is lower than the oxygen content atomic percentage of the oxygen-deficient transition metal oxide included in the first variable resistance layer and higher than the oxygen content atomic percentage of the oxygen-deficient transition metal oxide included in the second variable resistance layer;
forming an interlayer insulating layer covering the second electrode, the semiconductor layer, and the variable resistance layer;
forming a groove in a surface of the interlayer insulating layer that extends depthwise through to the variable resistance layer; and
forming a first electrode covering the variable resistance layer exposed from the groove.
